(19) United States
(12) Patent Application Publication
(10) Pub. No.: US 2011/0220007 A1
(43) Pub. Date: Sep. 15, 2011

(54) MODULAR SCOREBOARD AND METHOD OF ASSEMBLING SAME

(76) Inventors: Michael C. COWEN, Murray, KY (US); David Garrison, Murray, KY (US); David L. O'Neal, Murray, KY (US); Kerry R. Bush, McKenzie, TN (US)

(21) Appl. No.: 13/043,386

(22) Filed: Mar. 8, 2011

Related U.S. Application Data
(60) Provisional application No. 61/339,847, filed on Mar. 9, 2010.

(51) Int. Cl. A63F 1/18; H05K 13/00

(52) U.S. Cl. 116/222; 29/592.1

(57) ABSTRACT

A modular scoreboard and a method of assembling a modular scoreboard. A modular scoreboard includes a plurality of panels coupled to one another and attachable to a substrate, and at least one panel of the plurality of panels includes an attachment portion configured to attach the at least one panel to the substrate; an offset portion coupled to the attachment portion and configured to be spaced apart from the substrate to provide a conduit between the offset portion and the substrate when the at least one panel is attached to the substrate; and a coupling portion coupled to the offset portion and coupling the at least one panel to another panel of the plurality of panels.

### CROSS-REFERENCE TO RELATED APPLICATION

This application claims priority to and the benefit of U.S. Provisional Patent Application

No. 61/339,847, filed on Mar. 9, 2010 in the United States Patent and Trademark Office, the entire content of which is incorporated herein by reference.

### FIELD OF THE INVENTION

Aspects of embodiments of the present invention relate to a scoreboard, and more particularly, to a modular scoreboard and a method of assembling the same.

### BACKGROUND

Typical scoreboards for sporting or other events include a housing or similar support structure housing electronics, wiring, and output devices for indicating a score or other numerical representation. The housing of such a scoreboard is generally a large structure consisting of a single panel or several; panels welded or otherwise fixed to one another at the manufacturer's site. That is, a scoreboard is typically pre-assembled and transported to an installation site as such. However, this typically results in high shipping and installation costs due to the size and need for a crane or other special equipment for installation.

Further, it is often desired to replace an existing scoreboard, such as a malfunctioning or outdated scoreboard. Typically, replacement of an existing scoreboard is performed by removing the existing scoreboard and installing a new scoreboard, which as discussed above, is typically transported from the manufacturer and installed in a pre-assembled state, usually resulting in high shipping and installation costs. Additionally, permits may be needed for installing a new scoreboard.

### SUMMARY

According to an aspect of embodiments of the present invention, a modular scoreboard includes a plurality of panels that are each attachable to a substrate and coupled to one another. According to another aspect of embodiments of the present invention, a modular scoreboard is easily transported in a disassembled state, and further, is easily assembled without a need for expensive installation equipment, such as a crane. According to still another aspect of embodiments of the present invention, a modular scoreboard may be assembled, or retrofitted, onto an existing scoreboard, thereby reducing manufacturing, shipping, installation, and permitting costs. According to still another aspect of embodiments of the present invention, an indicator case is quickly and easily mountable to a display surface of a scoreboard or other signboard utilizing a tab-and-slot configuration. Further, wiring to an output device within the indicator case may be protected in a space between a display panel portion of the modular scoreboard and a substrate on which the modular scoreboard is mounted (e.g., a surface of an existing scoreboard). According to still another aspect of embodiments of the present invention, a modular scoreboard may have reduced size and/or weight for portability and increased options for installation, such as hanging one or more modular scoreboards (e.g., suspending a four-sided scoreboard in a center of a court).

According to one embodiment of the present invention, a modular scoreboard includes a plurality of panels coupled to one another and attachable to a substrate, and at least one panel of the plurality of panels includes an attachment portion configured to attach the at least one panel to the substrate; an offset portion coupled to the attachment portion and configured to be spaced apart from the substrate to provide a conduit between the offset portion and the substrate when the at least one panel is attached to the substrate; and a coupling portion coupled to the offset portion and coupling the at least one panel to another panel of the plurality of panels.

The substrate may be a display panel of another scoreboard. In one embodiment, the coupling portion includes a tab received in an opening formed in the another panel and engaging a portion of the another panel proximate the opening, the tab being slidable relative to the opening for engaging the portion of the another panel.

The modular scoreboard may further include an indicator mounted on the offset portion of the at least one panel. In one embodiment, the at least one panel has at least one first opening formed in the offset portion, and the indicator includes at least one tab received in the at least one first opening and engaging a portion of the offset portion proximate the at least one first opening, the at least one tab being slidable relative to the at least one first opening for engaging the portion of the offset portion. The at least one panel may have a second opening formed in the offset portion for passing wiring connected to an output device of the indicator therethrough to the conduit. In one embodiment, the indicator includes a case including the at least one tab; a cover mounted to the case; and an output device enclosed by the case and the cover.

In one embodiment, a modular scoreboard further includes a hinge coupling panels of the plurality of panels to each other. In one embodiment, a modular scoreboard further includes a display surface including outer surfaces of the panels. The modular scoreboard may further include a graphic design on the display surface.

In one embodiment, a modular scoreboard further includes at least one appendage portion coupled to at least one of the panels at a peripheral portion thereof. The modular scoreboard may further include a side rail coupled to a side of one of the panels and enclosing the conduit on the side of the panel. The modular scoreboard may further include a cover coupled to ends of the panels and enclosing the conduits of the panels on the ends. The at least one panel may further include at least one stiffener on an inner surface of the offset portion. In one embodiment, each panel of the plurality of panels includes an attachment portion configured to attach the panel to the substrate.

According to another embodiment of the present invention, a modular scoreboard includes at least one panel including a display surface having at least one first opening; and an indicator mounted on the at least one panel and including at least one tab received in the at least one first opening and engaging a portion of the at least one panel proximate the at least one first opening.

In one embodiment, the indicator includes a case including the at least one tab; a cover mounted to the case; and an output device enclosed by the case and the cover. In one embodiment, the display surface of the at least one panel has a second opening, and the case of the indicator has an opening corresponding to the second opening of the at least one panel, the opening of the indicator and the second opening of the at least one panel being configured to pass wiring therethrough for electrically connecting the output device to a control module. The at least one panel may include a plurality of panels coupled to one another and attachable to a substrate, and the display surface may be spaced apart from the substrate to define a conduit therebetween when the panels are attached to the substrate.

According to another embodiment of the present invention, a method of assembling a modular scoreboard including a plurality of panels includes attaching panels of the plurality of panels to a substrate such that display portions of the panels are spaced apart from the substrate to define at least one conduit between the display portions and the substrate; coupling the panels to one another; and mounting an indicator on at least one of the panels.

The substrate may be a display panel of another scoreboard. In one embodiment, coupling the panels to one another includes inserting a tab of one of the panels into an opening formed in another one of the panels and slidably engaging the tab with a portion of the another one of the panels proximate the opening.

In one embodiment, mounting the indicator on the at least one of the panels includes inserting at least one tab of a case of the indicator into at least one corresponding first opening formed in the display portion of the at least one of the panels and slidably engaging the at least one tab with at least one corresponding portion of the at least one of the panels proximate the at least one first opening.

In one embodiment, the method further includes electrically connecting an output device of the indicator to a control module through wiring passing through an opening of the case and a second opening formed in the display portion of the at least one of the panels.

Additional aspects and/or advantages of embodiments of the present invention are set forth in the following description and accompanying drawings, or may be obvious in view thereof to those skilled in the art.

### BRIEF DESCRIPTION OF THE DRAWINGS

The above and other features and advantages will become more apparent to those of ordinary skill in the art by describing in detail some exemplary embodiments of the present invention with reference to the attached drawings, in which:

FIG. 1 is a perspective view of a modular scoreboard according to an embodiment of the present invention shown mounted on a substrate;

FIG. 2 is a top view of the modular scoreboard of FIG. 1;

FIG. 3 is a rear perspective view of the modular scoreboard of FIG. 1 shown removed from the substrate;

FIG. 4 is a rear perspective view of a panel of the modular scoreboard of FIG. 1;

FIG. 5 is a rear perspective view of two panels of the modular scoreboard of FIG. 1 coupled to each other;

FIG. 6 is a top view of two panels and two side rails of the modular scoreboard of FIG. 1;

FIG. 7A is a front view of an indicator of a modular scoreboard according to an embodiment of the present invention;

FIG. 7B is a sectional view of the indicator of FIG. 7A, taken along the line 7B-7B;

FIG. 7C is a detail sectional view of a portion of the indicator of FIG. 7B, taken at the region 7C;

FIG. 7D is a detail sectional view of a portion of the indicator of FIG. 7B, taken at the region 7D;

FIGS. 8A-8C are perspective, front, and side views, respectively, of a case of the indicator of FIG. 7A;

FIG. 9 is an exploded perspective view of an indicator of a modular scoreboard according to another embodiment of the present invention;

FIG. 10A is a front view of the indicator of FIG. 9;

FIG. 10B is a sectional view of the indicator of FIG. 10A, taken along the line 10B-10B;

FIG. 10C is a detail sectional view of a portion of the indicator of FIG. 10B, taken at the region 10C;

FIGS. 11A-11C are front, side, and rear views, respectively, of a case of the indicator of FIG. 9;

FIG. 12 is an exploded perspective view of an indicator of a modular scoreboard according to another embodiment of the present invention;

FIGS. 13A and 13B are front and side views, respectively, of the indicator of FIG. 12;

FIGS. 14A-14C are front, side, and rear views, respectively, of a′case of the indicator of FIG. 12;

FIG. 15 is an exploded perspective view of a driver assembly of a modular scoreboard according to another embodiment of the present invention;

FIGS. 16A and 16B are front and side views, respectively, of the driver assembly of FIG. 15;

FIGS. 17A-17C are front, side, and rear views, respectively, of a case of the driver assembly of FIG. 15;

FIG. 18 is a view of an indicator and wiring of a modular scoreboard according to an embodiment of the present invention;

FIG. 19 is a schematic side view of a cover of a modular scoreboard according to an embodiment of the present invention;

FIG. 20 is a schematic side view of a cover of a modular scoreboard according to another embodiment of the present invention;

FIG. 21 is a schematic side view of a cover of a modular scoreboard according to another embodiment of the present invention;

FIG. 22 is a schematic front view of a panel of a modular scoreboard according to another embodiment of the present invention;

FIG. 23 is a schematic perspective view of a panel of a modular scoreboard according to another embodiment of the present invention;

FIG. 24 is a schematic perspective view of a panel of a modular scoreboard according to another embodiment of the present invention;

FIG. 25 is a schematic perspective view of a portion of a panel of a modular scoreboard according to another embodiment of the present invention;

FIG. 26 is a schematic perspective view of a panel of a modular scoreboard according to another embodiment of the present invention;

FIG. 27 is a schematic perspective view of a panel of a modular scoreboard according to another embodiment of the present invention;

FIG. 28 is a view of the panel of FIG. 27 mounted on a substrate;

FIG. 29 is a schematic perspective view of a portion of a panel of a modular scoreboard according to another embodiment of the present invention;

FIG. 30 is a schematic perspective view of a portion of a mounting bracket of a modular scoreboard according to an embodiment of the present invention;

FIG. 31 is a schematic perspective view of a portion of a panel of a modular scoreboard according to another embodiment of the present invention;

FIG. 32 is a schematic perspective view of a modular scoreboard according to another embodiment of the present invention;

FIG. 33 is a flowchart showing tasks of a method of assembling a modular scoreboard according to another embodiment of the present invention;

FIG. 34 is a rear view of a mounting bracket mounting a control module according to an embodiment of the present invention;

FIG. 35 is a rear perspective view of the mounting bracket of FIG. 34;

FIG. 36 is a schematic view showing wiring connection points on a digit panel of an indicator of a modular scoreboard according to an embodiment of the present invention;

FIG. 37 is a schematic view of a driver board of a modular scoreboard according to an embodiment of the present invention; and

FIG. 38 is a schematic wiring layout of a modular scoreboard according to one embodiment of the present invention.

### DETAILED DESCRIPTION

Some exemplary embodiments will now be described more fully hereinafter with reference to the accompanying drawings; however, embodiments of the present invention may be embodied in different forms and should not be construed as limited to the exemplary embodiments illustrated and set forth herein. Rather, these exemplary embodiments are provided by way of example for understanding of the invention and to convey the scope of the invention to those skilled in the art.

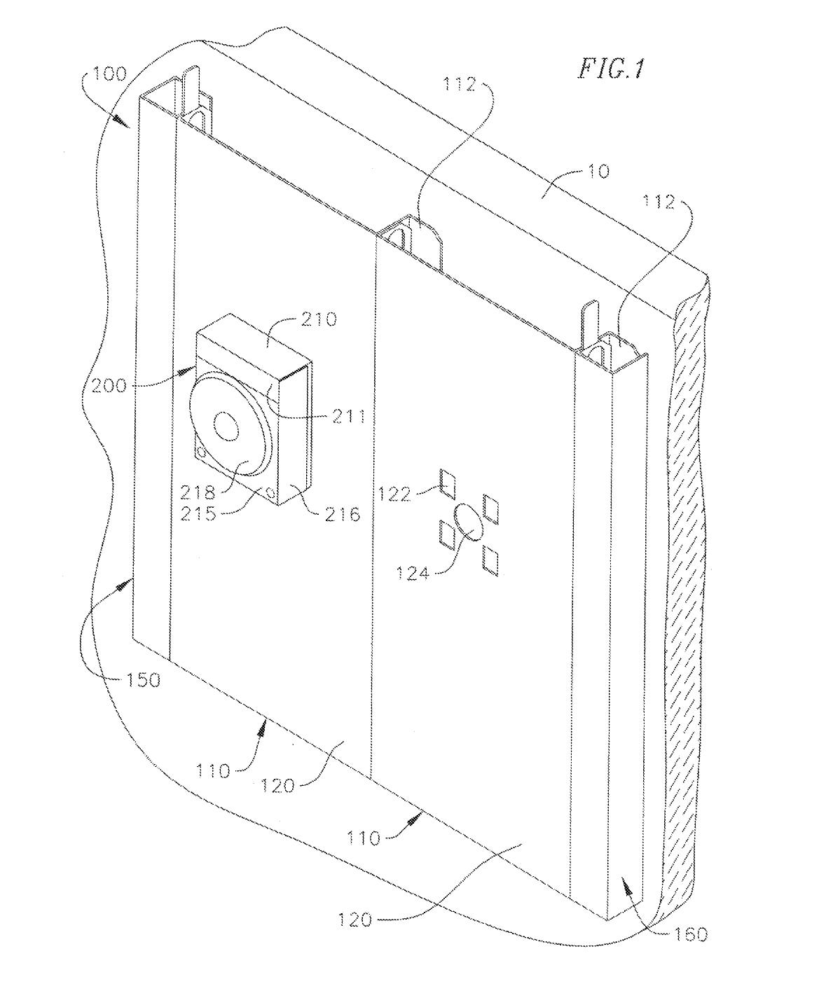

With reference to FIGS. 1-3, a modular scoreboard 100 according to one embodiment of the present invention includes one or more panels 110 attachable to a substrate 10, such as a display panel or other surface of another scoreboard (e.g., a pre-existing scoreboard which the modular scoreboard 100 retrofits). Although the modular scoreboard 100 shown in FIGS. 1-3 includes two panels 110 coupled to each other, embodiments of a modular scoreboard of the present invention are not limited thereto and, in other embodiments, the modular scoreboard 100 may have any other suitable number of panels 110, including one panel 110. Further, although the panels 110 are shown in FIG. 1 having a vertical orientation, in another embodiment, the panels 110 may be attached to the substrate 10 having a horizontal orientation.

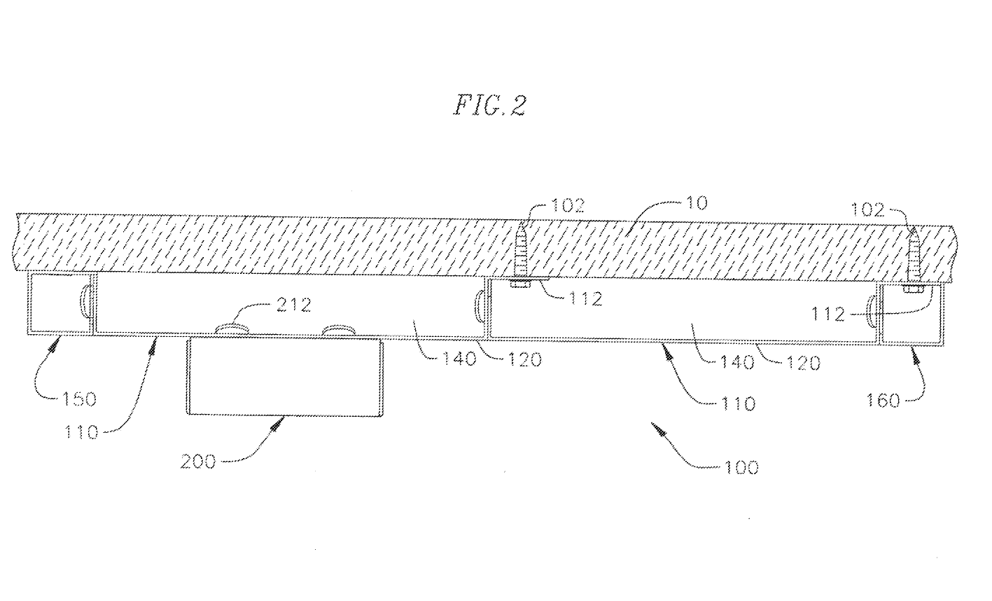

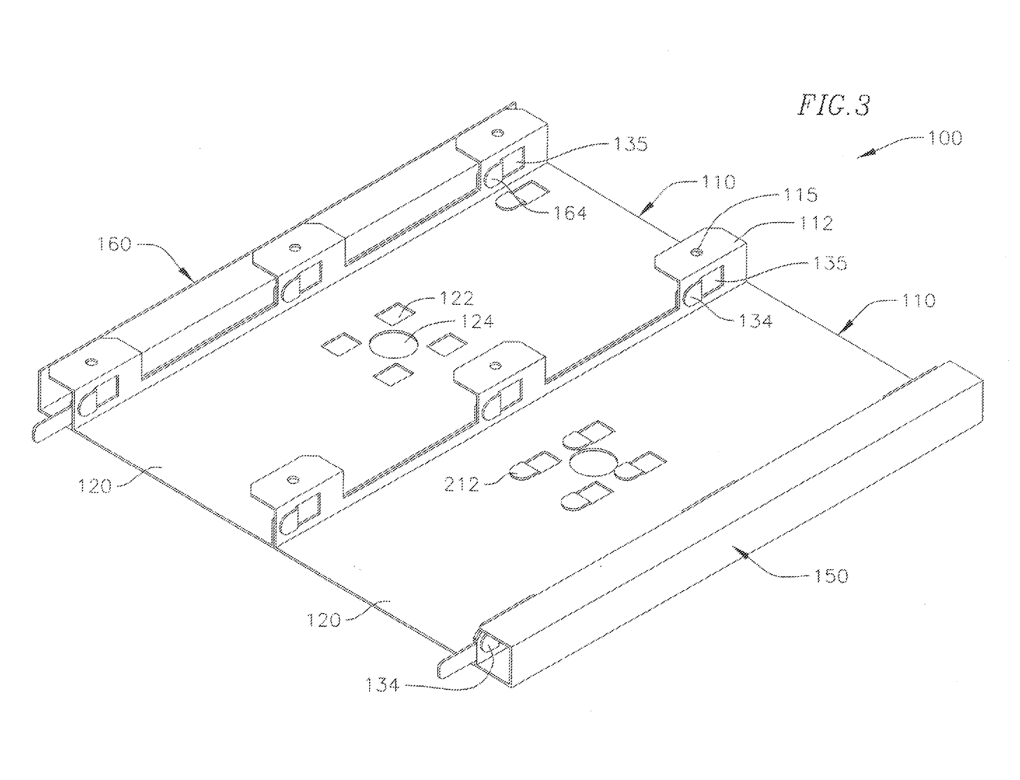

With reference to FIG. 4, the panel 110, according to one embodiment, includes one or more attachment portions 112 configured to attach the panel 110 to the substrate 10; an offset portion 120 coupled to the attachment portion 112 and configured to be spaced apart from the substrate 10 to provide a conduit 140 between the offset portion 120 and the substrate 10 when the panel 110 is attached to the substrate 10; and a coupling portion 132 coupled to the offset portion 120 and configured to couple the panel 110 to another panel 110. In one embodiment, the attachment portions 112 are offset and substantially parallel to the offset portion 120. Further, the attachment portions 112 are connected to the offset portion 120 by flanges 114, which, in one embodiment, are substantially perpendicular to each of the attachment portion 112 and the offset portion 120. The flanges 114 have openings 135 formed therein for receiving a tab 134 of the coupling portion 132 of another panel 110. While the panel 110 is shown in FIG. 4 having corresponding flanges 114 coupling the attachment portions 112 to the offset portion 120, in another embodiment, the panel 110 may have a single flange 114 extending along a length of the offset portion 120 and coupling all or some of the attachment portions 112 to the offset portion 120. Further, in one embodiment, as shown in FIG. 4, the panel 110 may have a stiffening rib 142 between the flanges 114. Further, in one embodiment, the attachment portions 112 have attachment holes 115 formed therein for attaching the panel 110 to the substrate 10 via a screw 102 (see FIG. 2) or other fastener.

The offset portion 120, in one embodiment, is a substantially flat plate having an outer surface forming at least a portion of a display surface of the modular scoreboard 100. In one embodiment, the offset portion 120 has one or more first openings 122 for mounting an indicator 200, and one or more second openings 124 for passing wiring therethrough from an output device of the indicator 200 to the conduit 140.

The coupling portions 132 are connected to the offset portion 120 and, in one embodiment, are substantially perpendicular to the offset portion 120. The coupling portions 132, in one embodiment, have tabs 134 protruding therefrom configured to be received in corresponding openings 135 of another panel 110 and to engage corresponding portions of the flanges 114 proximate the openings 135 for coupling the panels 110 to each other. While the panel 110 is shown in FIG. 4 having a plurality of coupling portions 132, each having a tab 134 thereon, in another embodiment, the panel 110 may have a single coupling portion 132 extending along a length of the offset portion 120 and having a plurality of tabs 134 thereon. Further, in one embodiment, as shown in FIG. 4, the panel 110 may have a stiffening rib 144 between the coupling portions 132.

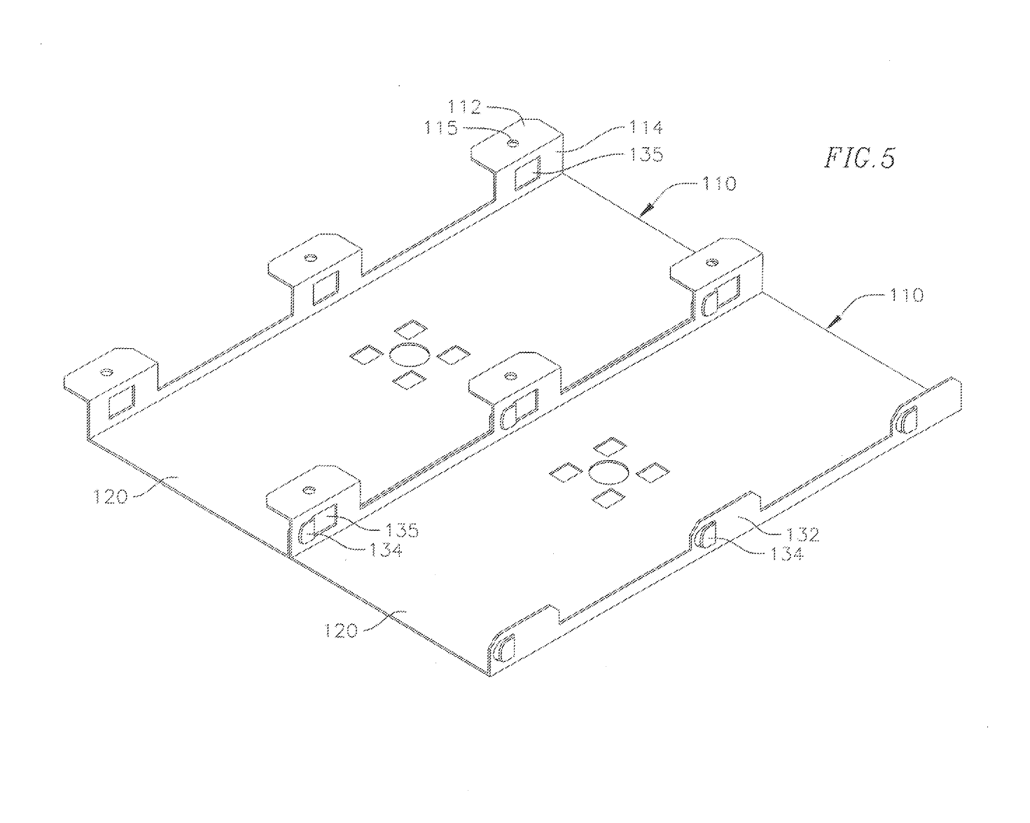

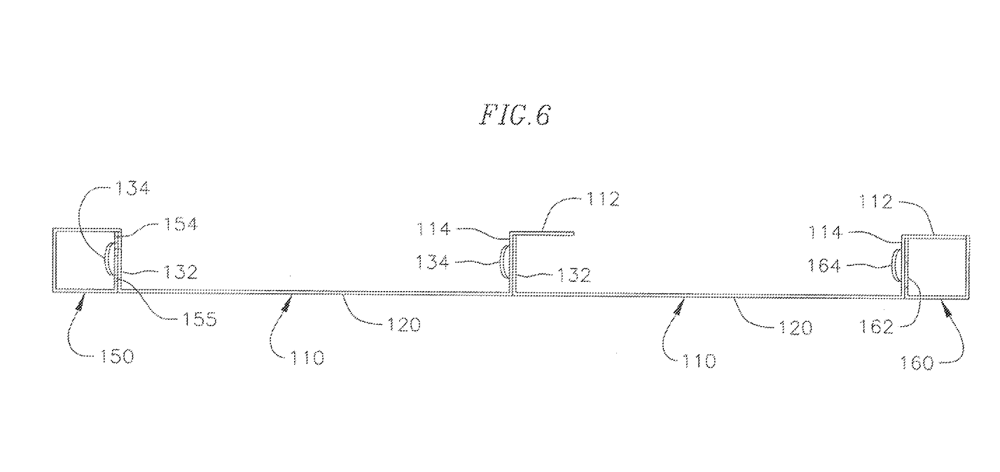

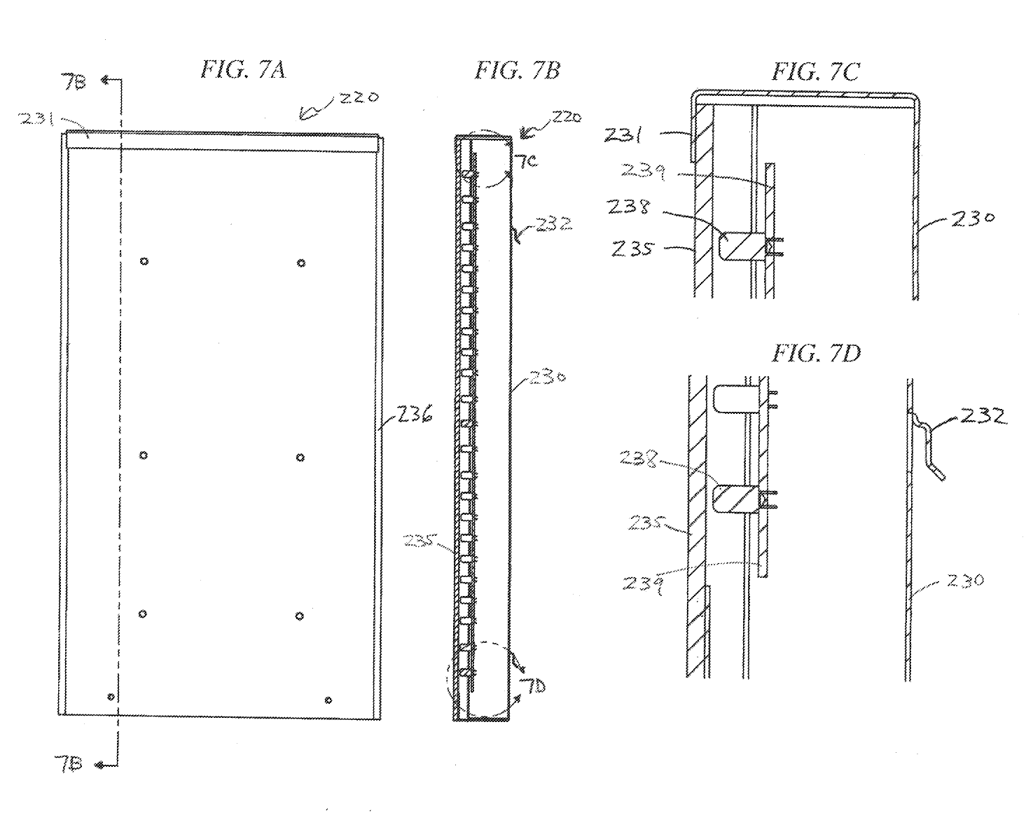

The panel 110, in one embodiment, is formed from an integral piece of material (as shown in FIG. 7), but alternatively, may be formed of separate pieces fixed together, such as by welding. The panel 110, in one embodiment, is formed of steel, such as by plasma cutting and bending, but alternatively, may be formed of any other suitable material and any other suitable manufacturing method or combination thereof, such as molding or stamping. Further, in one embodiment, the panel 110 may be coated for weather resistance, such as by powder coating, paint, or any other suitable coating.

Embodiments of the panels 110 according to the present invention may have any suitable dimensions, such as dimensions suitable for retrofitting an existing scoreboard to substantially cover a face of the existing scoreboard. For example, in one embodiment, the panels 110 may have a length of about six feet. The width of the panels 110 may be selected depending on the total width of the modular scoreboard 100 and the number of panels 110 desired. For example, in an embodiment of the modular scoreboard 100 having a greater number of panels 110, the panels 110 may have a larger width. In one embodiment, the panels 110 may have a width of about two feet. Further, a modular scoreboard 100 according to one embodiment of the present invention may have only a single panel 110, such as one panel 110 having a width of four feet, six feet, or any other desired width. In one embodiment, a modular scoreboard 100 may have a plurality of panels 110 wherein at least one of the panels 110 has a width different from a width of at least one other panel 110. For example, in one embodiment, a modular scoreboard 100 has a width of about eight feet and includes three central panels 110 each having a width of about two feet and an end panel 110 having a width of about one foot arranged on each side of the central panels 110. Further, the panels 110 may have any suitable depth (i.e. a distance between the attachment portion 112 and the offset portion 120 for providing a conduit 140 having a suitable depth. In one embodiment, a distance between the attachment portion 112 and the offset portion 120 may be about one inch.

With reference to FIG. 5, two of the panels 110 are shown coupled to each other according to, one embodiment of the present invention. The panels 110, in one embodiment, are coupled to each other at the coupling portion 132 of one of the panels 110 and the flange 114 of the other panel 110. More specifically, in one embodiment, as shown in FIG. 5, the tabs 134 of the coupling portion 132 of one of the panels 110 are inserted into the corresponding openings 135 formed in the flanges 114 of the other panel 110 and, subsequently, the tabs 134 are slidably engaged with corresponding portions of the flanges 114 proximate the openings 135 of the other panel 110. As such, the tabs 134 of the one panel 110 may be coupled by friction to the flanges 114 of the other panel 110. However, embodiments of the present invention are not limited thereto, and in other embodiment, the panels 110 may be coupled to each other by any other suitable device or method, such as via fasteners, hinges, clips, magnets, pins, or a combination thereof.

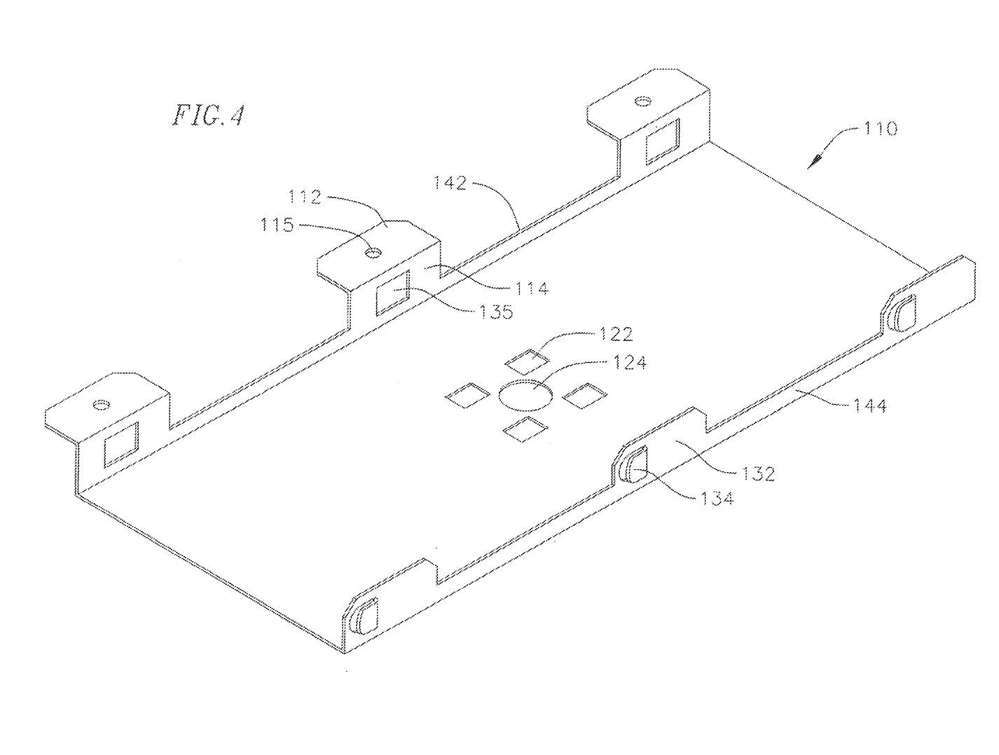

With reference to FIG. 6, two of the panels 110 are shown coupled to each other, as shown in FIG. 5, a first side rail 150 is coupled to one of the panels 110, and a second side rail 160 is coupled to the other panel 110 according to one embodiment of the present invention. The first and second side rails 150, 160, in one embodiment, have a square tubular shape, an angle shape, or any other suitable shape for protecting the conduits 140 from water, dust, and other debris, and in one embodiment are formed of steel, aluminum, or a plastic material, but alternatively, may be formed of any other suitable material. The first side rail 150, in one embodiment, has a flange 154 on one side and one or more openings 155 formed therein, and is mounted to one of the outermost panels 110 by inserting the tabs 134 of the coupling portion 132 of the panel 110 into the openings 155 of the first side rail 150 and slidably engaging corresponding portions of the flange 154 of the first side rail 150 proximate the openings 155 relative to the tabs 134. Further, in one embodiment, the second side rail 160 has one or more tabs 164 and is mounted to the other outermost panel 110 by inserting the tabs 164 into the openings 135 of the second panel 110 and slidably engaging the tabs 164 of the second side rail 160 with corresponding portions of the flanges 114 proximate the openings 135 of the second panel 110. Alternatively, in other embodiments, the first and second side rails 150, 160 may be mounted to the outermost panels 110 of the modular scoreboard 100 by any other suitable device or method, such as via fasteners.

The outer surfaces of the offset portions 120 of the panels 110 provide a display surface of the modular scoreboard 100. The display surface according to various embodiments of the present invention may provide a surface for mounting the indicators thereon, or in other embodiments, for displaying numerical or other representations through apertures therein. Further, the display surface may have a graphic design thereon. For example, a display surface of a modular scoreboard according to embodiments of the present invention may be a graphic display described in U.S. patent application Ser. No. 12/333,159, the disclosure of which is incorporated fully herein by reference. For example, a graphic display may be printed on a vinyl sheet and attached to the outer surfaces of the offset portions 120 of one or more of the panels 110. In another embodiment, for example, a graphic display may be directly printed on or applied to the offset portions 120 of one or more of the panels 110.

The modular scoreboard 100, according to one embodiment of the present invention, further includes one or more stiffeners mounted to an inner surface of the offset portion 120 of at least one of the panels 110. The stiffeners, in one embodiment, are formed of foam, such as polystyrene foam, or any other suitable material. In one embodiment, the modular scoreboard 100 includes a plurality of stiffeners spaced apart from one another at suitable locations on rear surfaces of the offset portion 120 of the panels 110. In one embodiment, a stiffener is about one inch thick and is about 16 inches long and about 3 inches wide. However, in other embodiments, the stiffeners may have any other suitable size. Further, in another embodiment or in addition to the stiffeners described above, the modular scoreboard 100 may include one or more reinforcing bars, such as a bar formed of steel or any other suitable material attached to a rear surface of at least one of the panels 110 by welding or any other suitable device or method. The stiffeners and/or reinforcing bars described above are configured to provide increased rigidity to the modular scoreboard 100 during transporting and after assembly.

Although scoreboards according to some exemplary embodiments are shown and described herein as having a generally rectangular shape, scoreboards according to other embodiments of the present invention may have any other desired shape. Further, one or more appendage portions may be attached at a perimeter portion of an embodiment of a modular scoreboard as shown and described herein. For example, appendage portions attachable to a scoreboard for providing a desired perimeter shape of a scoreboard are described in U.S. patent application Ser. No. 12/333,159, the disclosure of which is incorporated fully herein by reference. One or more such appendage portions may be attached to a modular scoreboard according to an embodiment of the present invention in order to provide the modular scoreboard with a desired perimeter shape. The one or more appendage portions may be attached for providing a desired display surface perimeter shape and graphic design perimeter shape as well.

According to one embodiment, a modular scoreboard may include one or more panels hinged together to be configured to fold and provide a reduced width. This may provide ease of shipment or may be desirable for particular installation options, such as to provide two or more portions of a modular scoreboard having different viewing angles. Further, the modular scoreboard having a hinge may be pre-wired by the manufacturer prior to shipment and installation. According to another embodiment, a modular scoreboard may have legs and/or wheels for portability. Further, according to one embodiment, a modular scoreboard may have telescoping legs for adjustability of height.

With further reference to FIGS. 1-3, an indicator 200, in one embodiment, is mounted on one of the panels 110 of the modular scoreboard 100. The indicator 200, in one embodiment, is mounted on a single panel 110, as shown in FIGS. 1-3, but in other embodiments, may be mounted on more than one of the panels 110. Further, a plurality of indicators 200, according to one or more embodiments, or one or more driver assemblies, as described below, may be mounted on one or more panels 110 of a modular scoreboard 100 of the present invention. The indicator 200, in one embodiment, has one or more tabs 212 for mounting the indicator 200 on the panel 110. More specifically, in one embodiment, the tabs 212 are receivable in the openings 122 of the panel 110 and slidably engageable with corresponding portions of the offset portion 120 of the panel 110 proximate the openings 122, such that the indicator 200 is coupled to the panel 110 via friction and gravity. Alternatively, the indicator 200, in other embodiments, may be coupled to the panel 110 by any other suitable device or method, such as via fasteners or adhesive.

With further reference to FIG. 1, the indicator 200, in one embodiment, includes a case 210 and a cover 215 mounted to the case 210. In one embodiment, the tabs 212 protrude from a rear surface of the case 210, and may be integrally formed from the case, such as by plasma cutting or punching and subsequently bent outward, or alternatively, may be formed separately and fixed to the case 210, such as by welding. Further, in one embodiment, the rear surface of the case 210 has an opening 214 formed therein (see FIG. 18) for passing wiring therethrough, such as for connecting the wiring to an output device in the indicator 200. The case 210, in one embodiment, has an upper portion 211 overlapping a portion of the cover 215 for preventing or reducing water from dripping inside the indicator 200. Similarly, in one embodiment, the cover 215 has side portions 216 overlapping side portions of the case 210 for further resistance to moisture and dust. The cover 215, in one embodiment, is snapped into the case 210 or is held against surfaces (e.g., side surfaces) of the case 210 by friction. Alternatively, the cover 215 may be mounted to the case 210 via any other suitable device or method, such as via fasteners.

The indicator 200 further includes one or more output devices (not shown) enclosed by the case 210 and the cover 215, such as one or more light emitting diodes (LEDs) for displaying a numerical representation (e.g., a score) or other information. The cover 215, in one embodiment, as shown in FIG. 1, has one or more raised portions 218 for providing improved visibility. For example, in one embodiment, the cover 215 has a plurality of raised portions 218 arranged in a pattern corresponding to a pattern of LEDs or other output devices of the indicator 200 for improved visibility (e.g., improved visibility at a long distance or at a wide viewing angle). Alternatively, the cover 215 may have a substantially flat outer surface. The case 210, in one embodiment, may be formed of steel, aluminum, or any other suitable material. The cover 215, in one embodiment, may be formed of a plastic material, such as a transparent or translucent plastic material, or any other suitable material. In one embodiment, the indicator 200 is coated (e.g., with a conformal coating) for weather resistance.

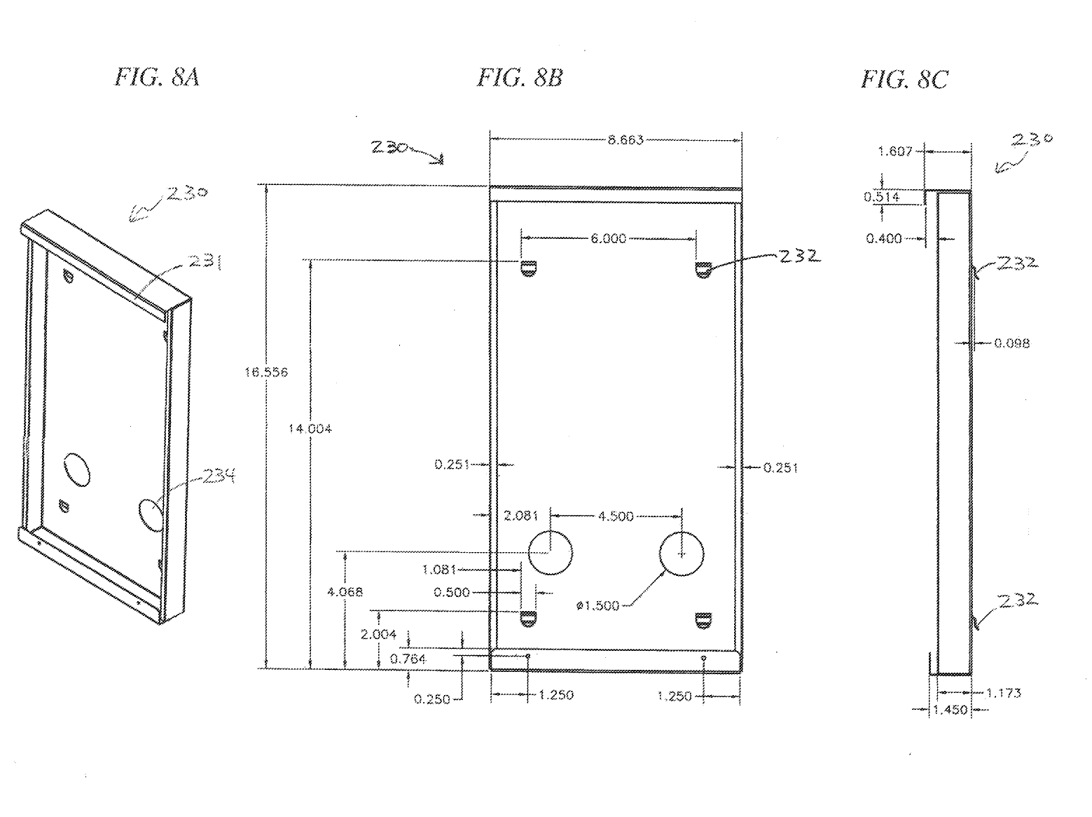

FIGS. 7A-7D show various views of an indicator 220 of a modular scoreboard according to an embodiment of the present invention, and FIGS. 8A-8C show various views of a case 230 of the indicator 220. The indicator 220 is configured to display a numerical digit and is configured similarly to the indicator 200 described above. In one embodiment, the indicator 220 includes the case 230 having an overlapping portion 231, one or more tabs 232, and at least one opening 234; a cover 235 having an overlapping portion 236; and one or more output devices 238 (e.g., LEDs), wherein each of the above-listed components has a structure and function similar to or the same as the corresponding component of the above-described indicator 200. The output devices 238 may be arranged on a board 239 located between the case, 230 and the cover 235. The dimensions shown in FIGS. 8B and 8C are dimensions according to one embodiment, but in other embodiments, the indicator 220 and the case 230 may have any other suitable dimensions.

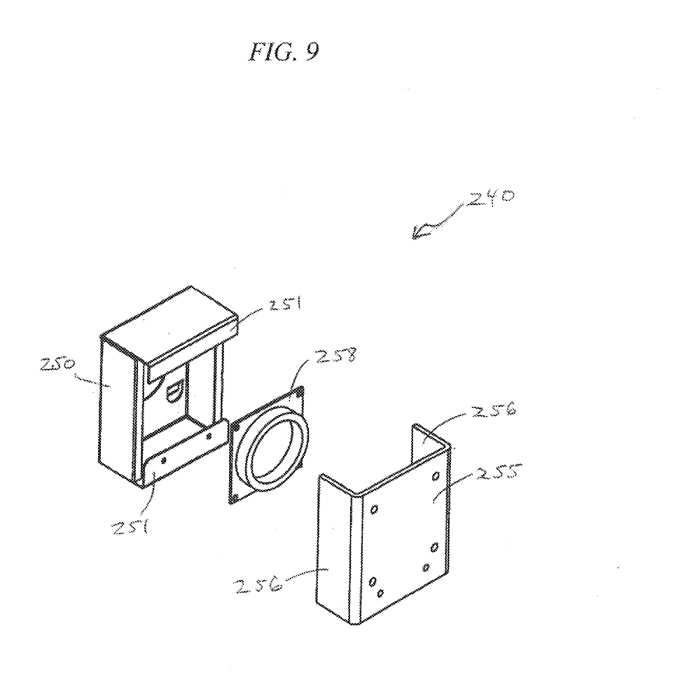

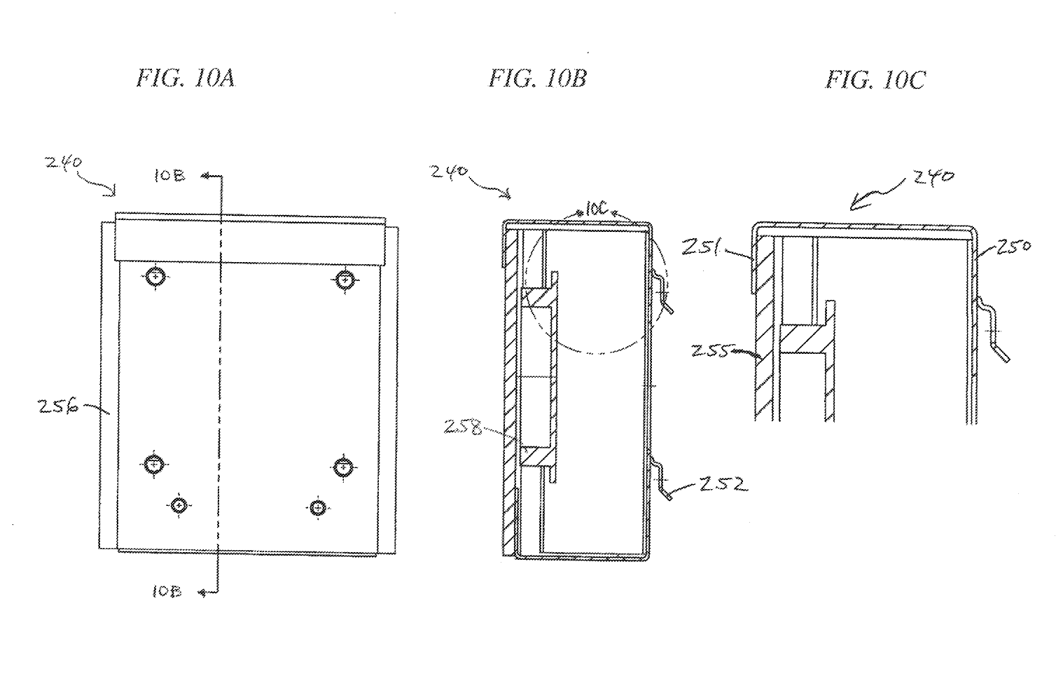

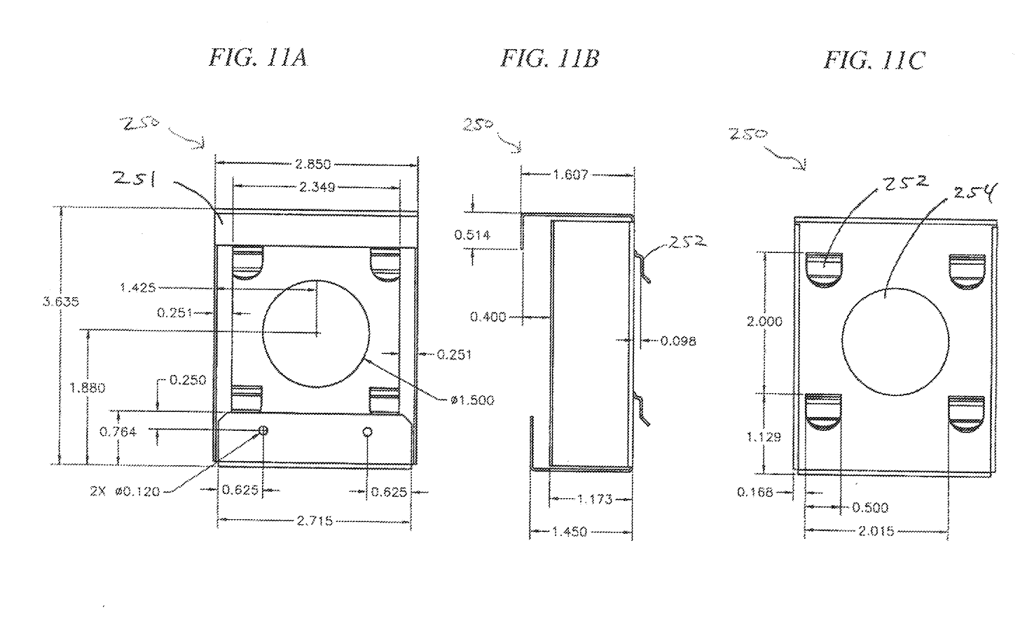

FIGS. 9-10C show various views of an indicator 240 of a modular scoreboard according to an embodiment of the present invention, and FIGS. 11A-11C show various views of a case 250 of the indicator 240. The indicator 240 is configured to display a circular or dot pattern and is configured similarly to the indicator 200 described above. In one embodiment, the indicator 240 includes the case 250 having an overlapping portion 251, one or more tabs 252, and at least one opening 254; and a cover 255 having an overlapping portion 256, wherein each of the above-listed components has a structure and function similar to or the same as the corresponding component of the above-described indicator 200. The indicator 240 may further include a lens 258 and one or more output devices (not shown) between the case 250 and the cover 255. The dimensions shown in FIGS. 11A-11C are dimensions according to one embodiment, but in other embodiments, the indicator 240 and the case 250 may have any other suitable dimensions.

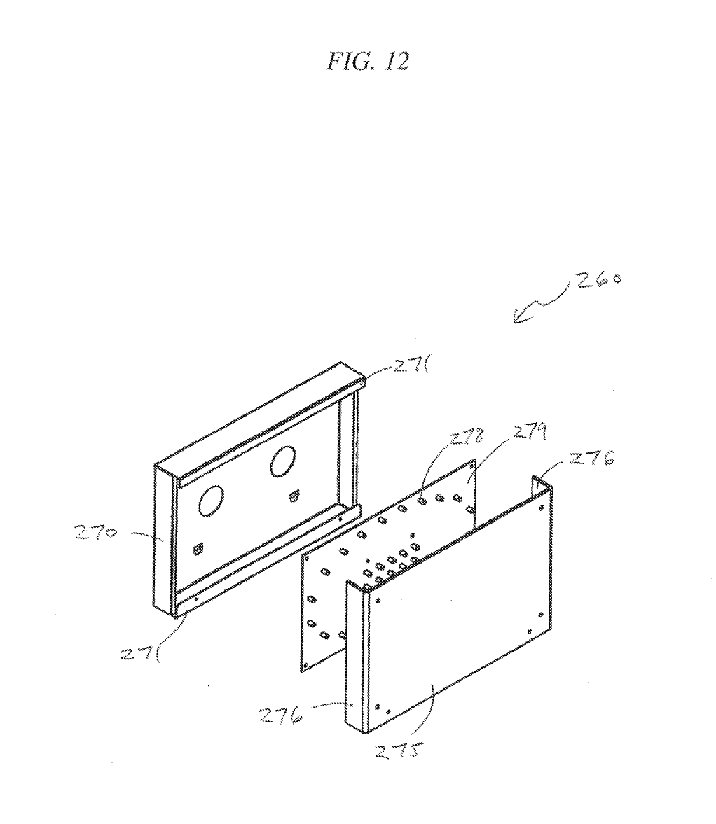

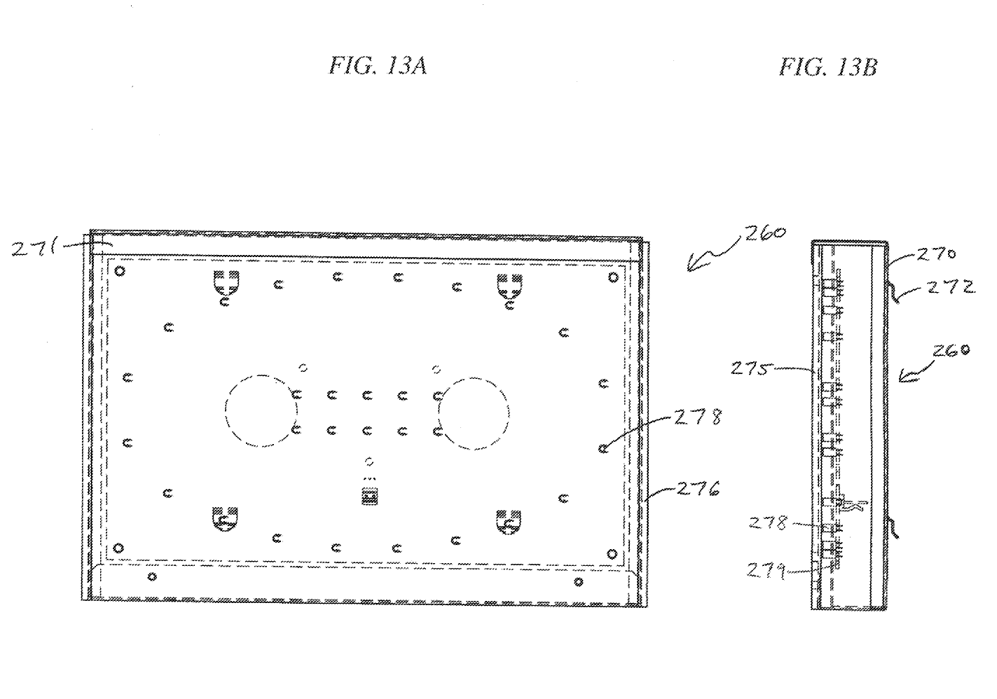

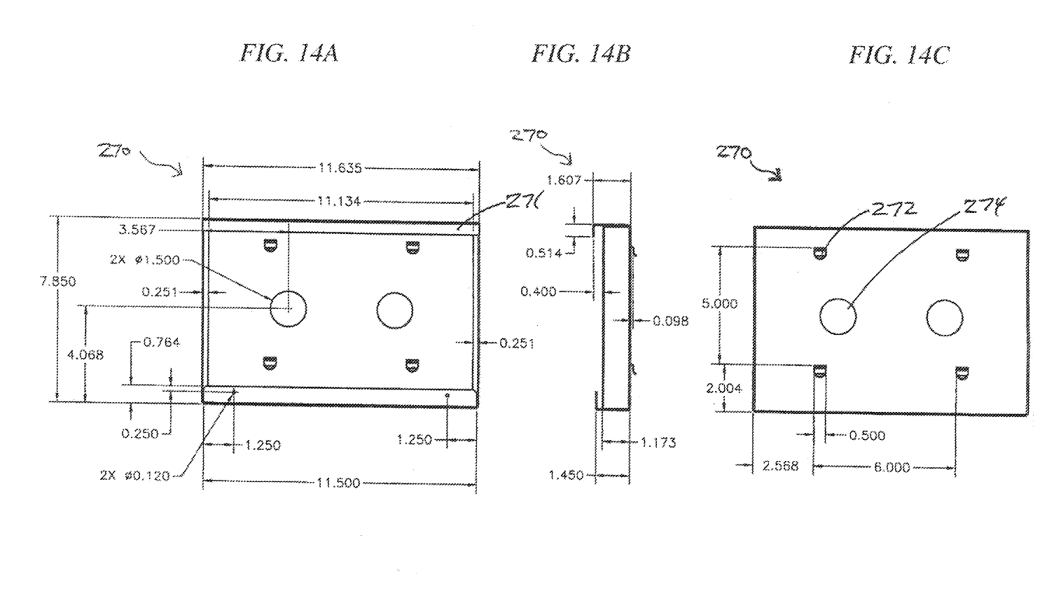

FIGS. 12-13B show various views of an indicator 260 of a modular scoreboard according to an embodiment of the present invention, and FIGS. 14A-14C show various views of a case 270 of the indicator 260. The indicator 260 is configured to display a pattern such as a possession-indicating pattern and is configured similarly to the indicator 200 described above. In one embodiment, the indicator 260 includes the case 270 having an overlapping portion 271, one or more tabs 272, and at least one opening 274; a cover 275 having an overlapping portion 276; and one or more output devices 278 (e.g., LEDs), wherein each of the above-listed components has a structure and function similar to or the same as the corresponding component of the above-described indicator 200. The output devices 278 may be arranged on a board 279 located between the case 270 and the cover 275. The dimensions shown in FIGS. 14A-14C are dimensions according to one embodiment, but in other embodiments, the case 270 may have any other suitable dimensions.

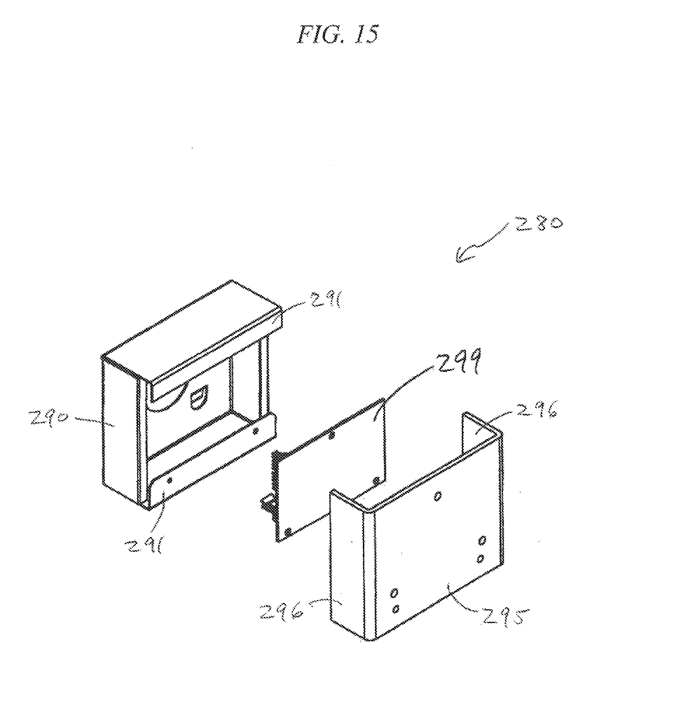

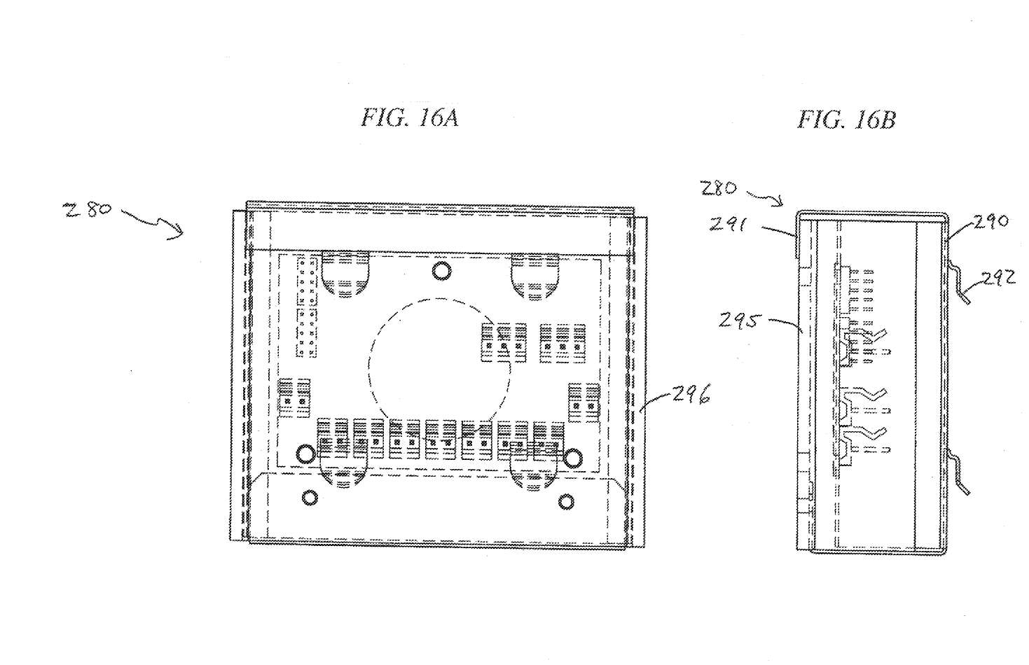

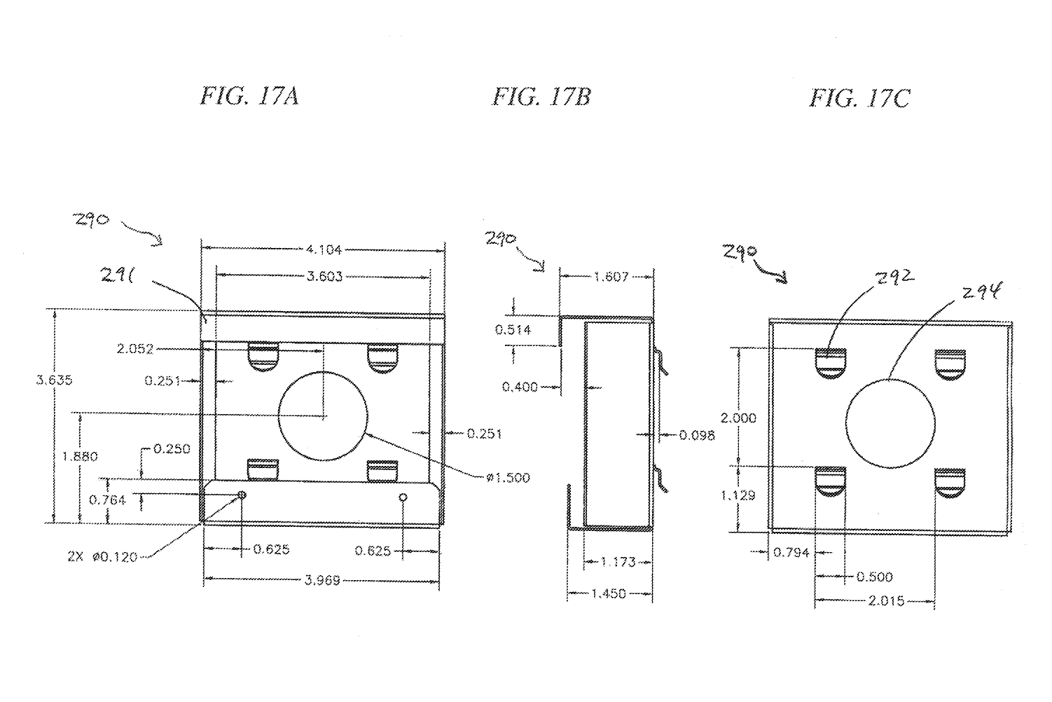

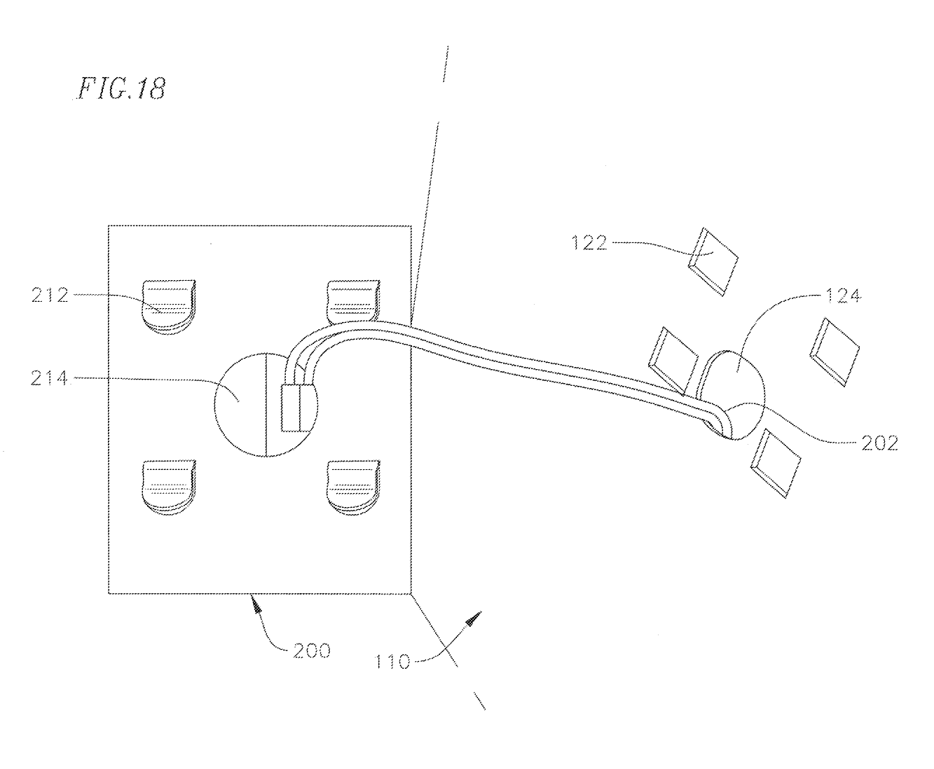

FIGS. 15-16B show various views of a driver assembly 280 of a modular scoreboard according to an embodiment of the present invention, and FIGS. 17A-17C show various views of a case 290 of the driver assembly 280. In one embodiment, the driver assembly 280 includes the case 290 having an overlapping portion 291, one or more tabs 292, and at least one opening 294; a cover 295 having an overlapping portion 296; and a driver board 299, wherein each of the above-listed components has a structure and function similar to or the same as the corresponding component of the above-described indicator 200. The dimensions shown in FIGS. 17A-17C are dimensions according to one embodiment, but in other embodiments, the case 290 may have any other suitable dimensions.

With reference to FIG. 18, an indicator of the modular scoreboard 100 according to an embodiment of the present invention is shown. For purposes of description, the indicator shown in FIG. 18 will be described herein as the indicator 200 described above and shown in FIGS. 1-3. However, the indicator shown in FIG. 18 may be one of the other indicators described above (e.g., one of the indicators 220, 240, 260), an indicator according to another embodiment of the present invention, or a driver assembly, such as the driver assembly 280 described above. As shown in FIG. 18, the indicator 200, in one embodiment, has a plurality of tabs 212 (e.g., one in each of four corners) to be received in corresponding openings 122 formed in the offset portion 120 of the panel 110 and to slidably engage corresponding portions of the offset portion 120 of the panel 110 proximate the openings 122. Further, in one embodiment, as shown in FIG. 18, the indicator 200 has an opening 214 (e.g., an opening formed in a rear side of the case 210) and wiring 202, such as wiring for electrically connecting an output device of the indicator to a control module of the modular scoreboard, passing through the opening 214 and an opening 124 formed in the offset portion 120 of the panel 110. As such, the wiring 202, in one embodiment, passes through and is protected in the conduit 140 between the substrate 10 and the offset portion 120 of the panel 110.

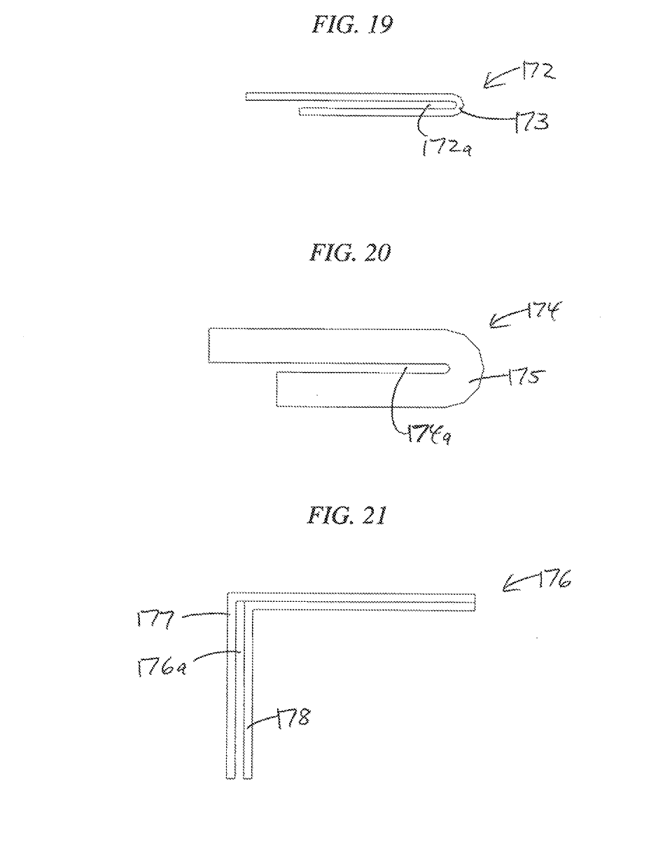

With reference to FIGS. 19-21, various embodiments of a cover of the modular scoreboard 100 are shown. The modular scoreboard 100 according to embodiments of the present invention may include one or more covers on top ends of the panels 110 and/or one or more covers on bottom ends of the panels 110. The covers shown in FIGS. 19-21 may function as a top cover, a bottom cover, or both. The covers, in one embodiment, protect the conduits 140 from water, precipitation, dust, and other debris. Further, a plurality of covers may be mounted on the top or bottom ends of the panels 110 (e.g., a cover on each of the panels 110), or a single cover may be mounted on a plurality of the panels 110 (e.g., a single cover spanning the top or bottom ends of all of the panels 110). According to the embodiments of the covers shown in FIGS. 19-21, the covers have a slot for receiving top or bottom edge portions of the panels 110 such that the cover may be slidably mounted onto the top or bottom edge portions of the panels 110. However, embodiments of the present invention are not limited thereto, and in other embodiments, the cover may be mountable to the top and/or bottom ends of the panels 110 by any other device or method, such as via fasteners. Further, the top and/or bottom ends of the panels 110 may have a contoured portion for facilitating sliding of the covers onto the top and/or bottom ends of the panels 110.

With reference to FIG. 19, a cover 172 according to one embodiment is formed of a U-shaped member 173 and has a slot 172a configured to receive the top or bottom edge portions of the panels 110 or flange portions thereof. In one embodiment, the U-shaped member 173 may be formed of a 22-gage sheet metal with one side having a length of about one inch and the other side having a length of about ¾ inch. According to another embodiment, as shown in FIG. 20, a cover 174, similar to the cover 172, is formed of a U-shaped member 175 and has a slot 174a configured to receive the top or bottom edge portions or flange portions thereof. In one embodiment, the U-shaped member 175 may be formed of a plastic material having a thickness of about 0.125 inches with one side having a length of about one inch and the other side having a length of about ¾ inch. According to still another embodiment, as shown in FIG. 21, a cover 176 is formed of two angular members 177 and 178 fixed to one another, such as via welding or spot-welding, and having a slot 176a therebetween configured to receive the top or bottom edge portions of the panels 110 therein. In one embodiment, the angular members 177 and 178 may be formed of a 22-gage sheet metal with one side having a length of about one inch and the other side having a length of about ¾ inch, and the slot 176a may have a width about the same as the thickness of the angular members 177 and 178. The covers 172, 174, 176 according to embodiments of the present invention may be formed of steel, aluminum, plastic, or any other suitable material. Also, the dimensions described above in embodiments of the covers 172, 174, 176 may be any other suitable dimensions in other embodiments.

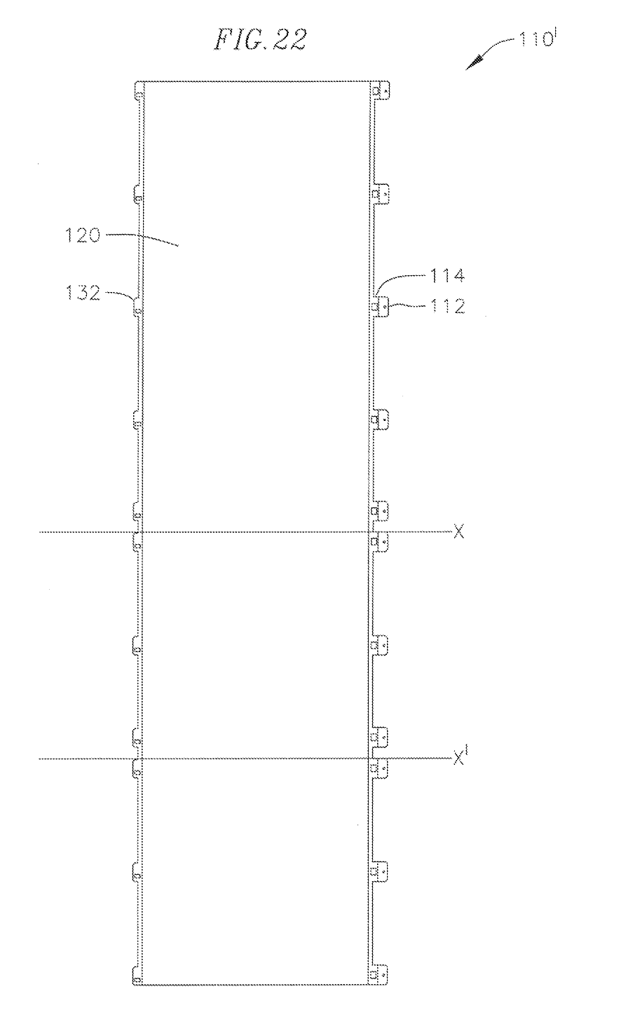

With reference to FIGS. 22-29, various panels of modular scoreboards according to additional embodiments of the present invention are shown. The panels shown in FIGS. 22-29 may be used instead of the panels 110 of the modular scoreboard 100 described above or in combination with the panels 110. In one embodiment, as shown in FIG. 22, a panel 110′ is similar to the panel 110 described above. The panel 110′ is shown in FIG. 22 in a state before the attachment portions 112, the flanges 114, and the coupling portions 132 have been bent relative to the offset portion 120. In the panel 110′, the number and positions of the attachment portions 112, the flanges 114, and the coupling portions 132 may be such that the panel 110′ may be cut into two or more panels and used in modular scoreboards having various lengths or heights (e.g., lengths or heights other than a standardized length of the panel 110′). For example, the panel 110′ may have a length of 8 feet, and two sets of the attachment portions 112, the flanges 114, and the coupling portions 132 may be positioned close to one another on either side of a 4-foot length and/or a 6-foot length, for example, so that when the panel 110′ is cut at a cut line X (e.g., a 4-foot line) or a cut line X′ (e.g., a 6-foot line), each of the resulting panels will have a set of the attachment portions 112, the flanges 114, and the coupling portions 132 near an end thereof.’

Referring to FIG. 23, according to another embodiment, a panel 180 has a flange 181 at one or both ends thereof (e.g., a top end and/or a bottom end). The flanges 181 provide protection against water and dust, for example, for a conduit between the panel 180 and the substrate 10 and may provide rigidity to the panel 180. The flanges 181, in one embodiment, may be formed having a width and a depth that are the same or substantially the same as those of the panel 180. Further, in one embodiment, covers may be installed on the flanges 181 for additional protection, such as one of the covers 172 and 174 described above.

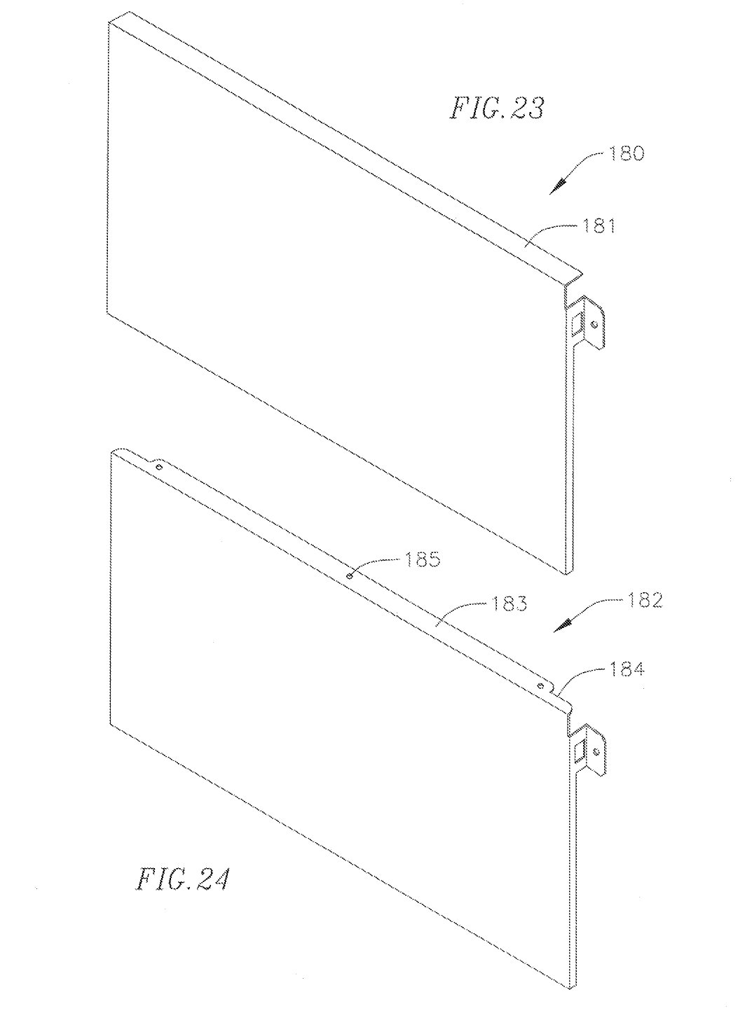

With reference to FIG. 24, a panel 182 according to another embodiment has a flange 183 at one or both ends thereof (e.g., a top end and/or a bottom end). The flanges 183 provide protection against water and dust, for example, for a conduit between the panel 182 and the substrate 10 and may provide rigidity to the panel 182. The flanges 183, in one embodiment, may be formed having a width and a depth that are the same or substantially the same as those of the panel 182. The flanges 183, in one embodiment, have contoured ends 184 configured such that multiple panels 182 may be nested, such as for storage or shipping. Also, in one embodiment, one or more tooling holes 185 may be formed in the flanges 183. Further, in one embodiment, covers may be installed on the flanges 183 for additional protection, such as one of the covers 172 and 174 described above.

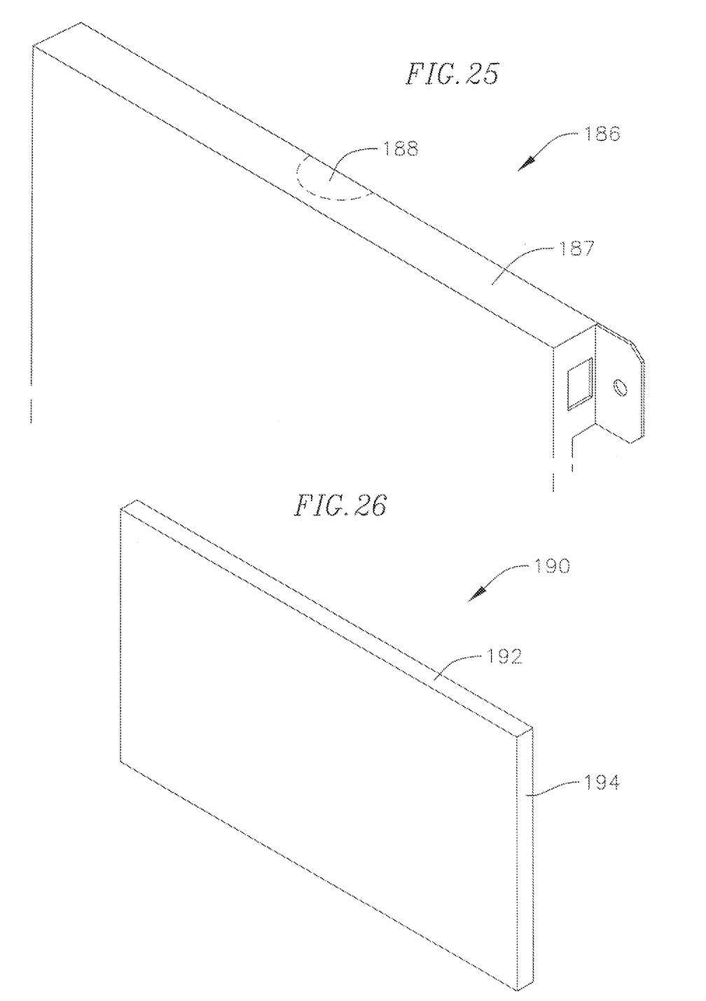

As shown in FIG. 25, a panel 186 according to one embodiment has a flange 187 at one or both ends thereof (e.g., a top end and/or a bottom end). The flanges 187 provide protection against water and dust, for example, for a conduit between the panel 186 and the substrate 10 and may provide rigidity to the panel 186. The flanges 187, in one embodiment, may be formed having a width and a depth that are the same or substantially the same as those of the panel 186. Further, the flanges 187 include one or more punch-type knockout portions 188 that are removable before or after installation, such as for passing wiring therethrough.

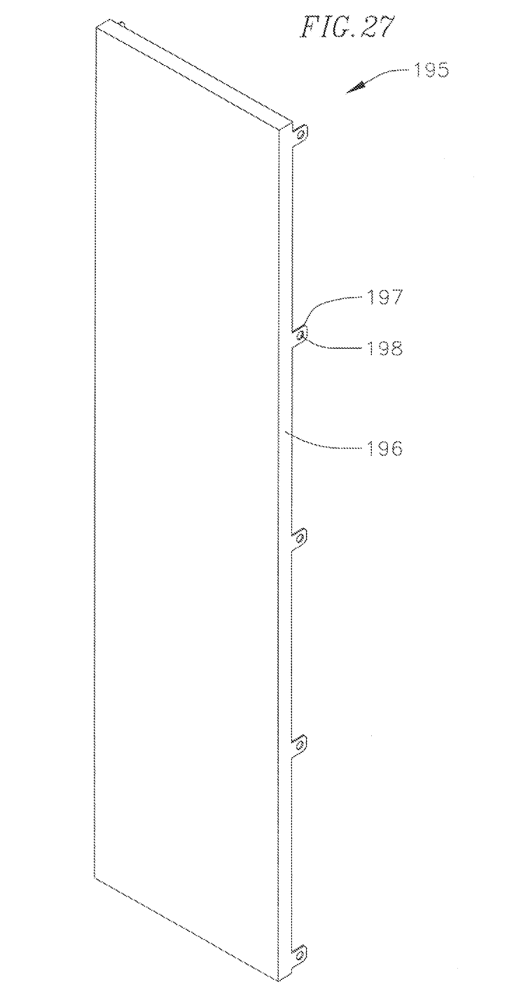

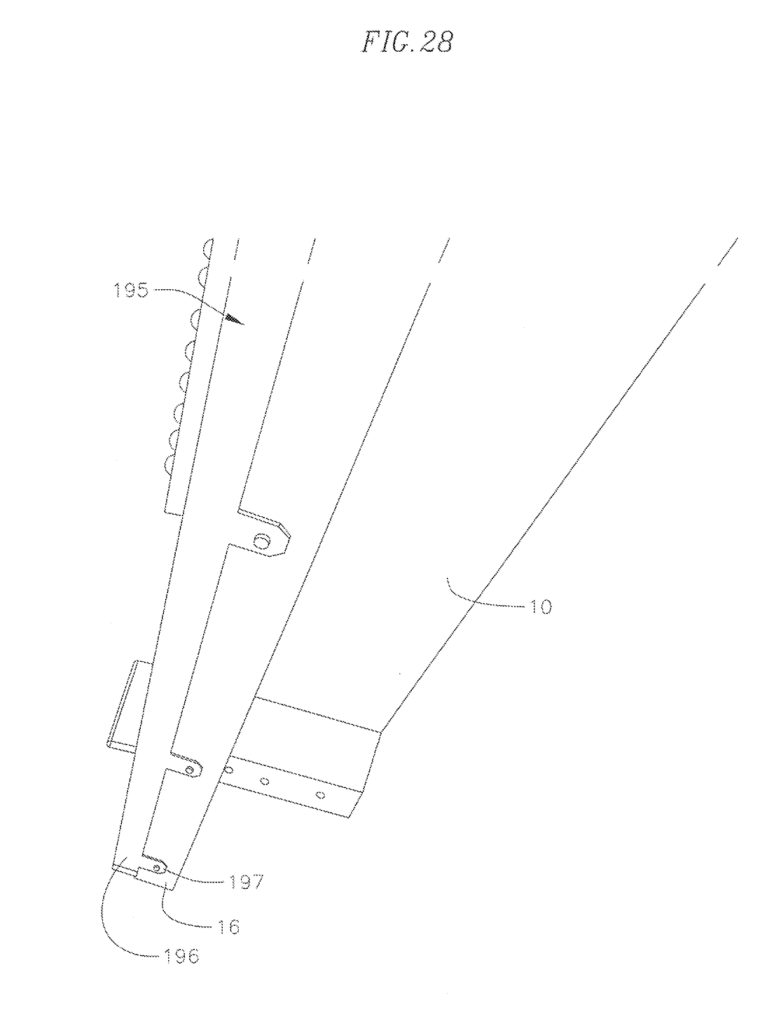

With reference to FIG. 26, a panel 190 according to another embodiment has a flange 192 at one or both ends thereof (e.g., a top end and/or a bottom end) and a flange 194 at one or both sides thereof (e.g., a left side and/or a right side). In one embodiment, the flanges 192 and 194 surround the perimeter of the panel 190 and enclose a conduit between the panel 190 and the substrate 10. The flanges 192 and 194 provide protection against water and dust, for example, for a conduit between the panel 190 and the substrate 10 and may provide rigidity to the panel 190. The flanges 192, in one embodiment, may be formed having a width and a depth that are the same or substantially the same as those of the panel 190. Similarly, the flanges 194, in one embodiment, may be formed having a length and a depth that are the same or substantially the same as those of the panel 190. The panel 190, in one embodiment, is attachable at one or both of the flanges 192, 194 to the substrate 10, such as to angle structures protruding from the substrate 10. Further, in one embodiment, the panel 190 is coupled to another panel 190 using drill point sheet metal screws, or any other suitable fastener or coupling device, such as through one or both of the flanges 192, 194. However, embodiments of the invention are not limited thereto and, in other embodiments, the panels 190 may be attached to the substrate 10 and/or coupled to each other by any other suitable device or method.

With reference to FIG. 27, a panel 195 according to another embodiment has a flange 196 at one or both ends or sides thereof (e.g., a left or right side) and one or more tabs 197 protruding therefrom for attaching the panel 195 to a side surface of a structure, such as an existing scoreboard or another substrate. In one embodiment, a flange 196 and the tabs 197 are on one side of the panel 195, and the panel 195 is an outermost panel 195 of a modular scoreboard, such that the tabs 197 are attachable to a side of an existing scoreboard or a filler panel extending from an existing scoreboard. The flanges 196, in one embodiment, may be formed having a length and a depth that are the same or substantially the same as those of the panel 195. In one embodiment, the tabs 197 have fasteners holes 198 formed therethrough for attaching the tabs 197 to a structure using screws or other fasteners through the fastener holes 198.

As shown in FIG. 28, the panel 195 may be mounted to the substrate 10 (e.g., an existing scoreboard), and attached at the tabs 197 protruding from the flange 196 to a filler panel 16 that is attached to the substrate 10. For example, in one embodiment, the panel 195 extends past an end (e.g., a side end) of the substrate 10, and the filler panel 16 connects the panel 195 at the tabs 197 to the substrate 10. In one embodiment, the tabs 197 are connected to the filler panel 16 with screws or other fasteners through the fastener holes 198 but, alternatively, the tabs 197 may be connected to the filler panel 16 by any other suitable device. The filler panel 16, in one embodiment, may be an angle structure (e.g., a bent piece of sheet metal), having a width of about 1.5 inches and a length generally corresponding to the distance by which the panel 195 extends past the substrate 10.

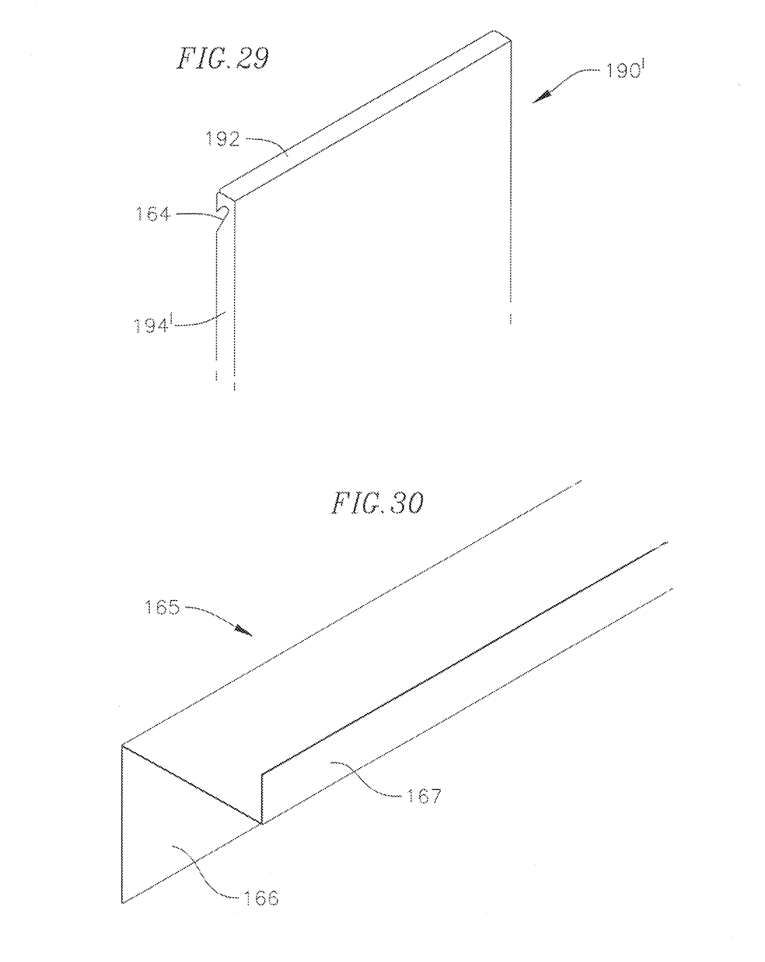

With reference to FIG. 29, a panel 190′ according to another embodiment of the present invention is similar to the panel 190 described above and includes a flange 192 at one or both ends thereof (e.g., a top end and/or a bottom end) and a flange 194′ at sides thereof (e.g., a left side and a right side). In one embodiment, the flanges 192 and 194′ surround the perimeter of the panel 190′ and enclose a conduit between the panel 190′ and the substrate 10, similar to the panel 190. In one embodiment, the panel 190′ has a depth of about 4.5 inches, but is not limited thereto in other embodiments. Each of the flanges 194′ has a slot 164 near the top end of the panel 190′ which is configured to receive a rod or a bracket therein for hanging the panel 190′ on the substrate 10. Further, in one embodiment, the panel 190′ may be coupled to the substrate 10 at the bottom end and/or to other panels 190′ at the sides using drill point sheet metal screws, or any other suitable fastener or coupling device, such as through one or both of the flanges 192, 194′.

With reference to FIG. 30, a mounting bracket 165 according to an embodiment of the present invention is configured to hang or mount a panel according to an embodiment of the present invention on the substrate 10. The mounting bracket, in one embodiment, is formed of an angle 166 and an upward portion 167 extending vertically from an end of the angle 166 in an upward direction. With reference to FIG. 31, a panel 190″ according to another embodiment of the present invention is similar to the panel 190 described above and includes a flange 192′ at a top end thereof. The flange 192′ is configured to engage the bracket 165 or a similar bracket for hanging the panel 190″ on the substrate 10. In one embodiment, the panel 190″ includes an angle (not shown) that is attached (e.g., cinched or welded) near the top of the rear side of the panel 190″ to provide a slot for receiving the upward portion 167 of the bracket 165. Further, in one embodiment, the panel 190″ may include flanges at the bottom end and the sides and may be coupled to the substrate 10 at the bottom end and/or to other panels 190″ at the sides using drill point sheet metal screws, or any other suitable fastener or coupling device.

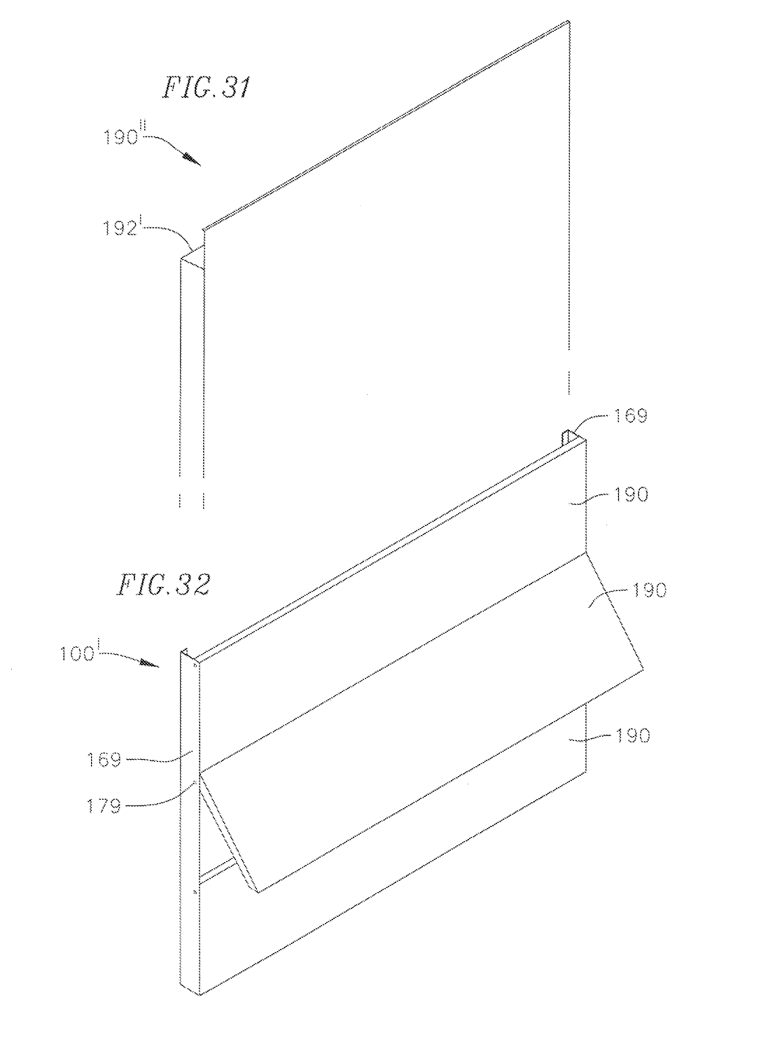

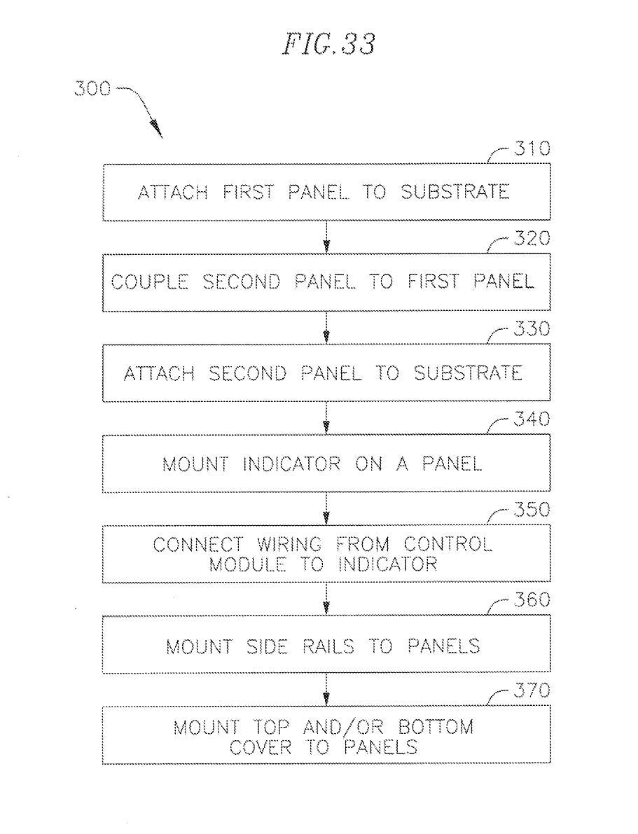

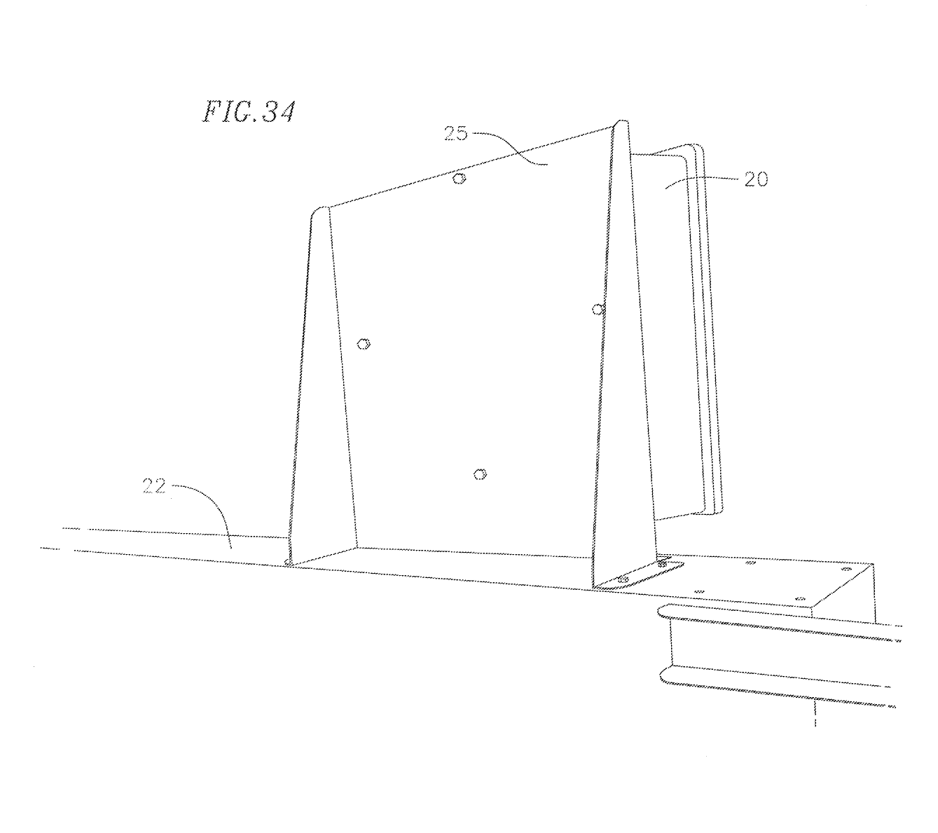

With reference to FIG. 32, a modular scoreboard 100′ according to another embodiment of the present invention includes one or more of the panels 190 or, alternatively, one or more of the other panels described above or a combination thereof. The panels 190, in one embodiment, are pivotably mounted to a pair of mounting brackets 169 at pivots 179 at opposite side ends of the panels 190. That is, the panels 190 may be swung open about the pivots 179 to allow access to the back sides of the panels 190. In another embodiment, the panels 190 may be pivotably mounted at top and/or bottom ends to a pair of mounting brackets that are located at the top and bottom of the modular scoreboard 100′ such that the panels 190 may be swung open similar to a door for providing access to the back side thereof.

A method 300 of assembling a modular scoreboard according to an embodiment of the present invention is shown in FIG. 33. Although the method 300 is described herein with respect to the modular scoreboard 100 described above and shown in FIGS. 1-3, the method 300 may also be performed to assemble a modular scoreboard according to other embodiments of the present invention. The method 300 includes a task 310 of attaching a first panel 110 to the substrate 10. As described herein, the substrate 10 may be a display panel of another existing scoreboard to be retrofitted by the scoreboard 100, or alternatively, may be any other suitable facade or surface. The first panel 110, in one embodiment, is a first panel of a plurality of panels 110 of the modular scoreboard 100. Further, in one embodiment, with reference to FIGS. 1-3, the first panel 110 is attached at the attachment portions 112 to the substrate 10, such as via fasteners 102 (see FIG. 2) inserted through the attachment holes 115 formed in the attachment portions 112. In other embodiments, the first panel 110 may be attached to the substrate 10 by any other suitable device or method.

Further, in one embodiment, the method 300 includes a task 320 of coupling a second panel 110 to the first panel 110. According to one embodiment, the second panel 110 is coupled to the first panel 110 by inserting the tabs 134 of the coupling portion 132 of the second panel 110 into the openings 135 of the first panel 110 and slidably engaging the tabs 134 of the second panel 110 with corresponding portions of the flanges 114 proximate the openings 135 of the first panel 110. As such, the tabs 134 of the second panel 110 may be friction-coupled to the flanges 114 of the first panel 110.

In one embodiment, the method 300 further includes a task 330 of attaching the second panel 110 to the substrate 10. The second panel 110 may be attached to the substrate 10 in the same manner in which the first panel 110 is attached to the substrate. That is, in one embodiment, the second panel 110 is attached at the attachment portions 112 to the substrate 10, such as via fasteners 102 (see FIG. 2) inserted through the attachment holes 115 formed in the attachment portions 112. In other embodiments, the first panel 110 may be attached to the substrate 10 by any other suitable device or method. Although FIG. 33 shows only first and second panels 110 being attached to the substrate 10, in other embodiments, any desired number of panels 110 of the modular scoreboard 100 may be attached to the substrate 10 and coupled to each other, such as by the tasks 320 and 330 described above.

In one embodiment, the method 300 further includes a task 340 of mounting an indicator 200 on at least one of the first and second panels 110. As described above with respect to FIG. 18, the indicator 200, in one embodiment, is mounted on at least one of the panels 110 by inserting the tabs 212 in corresponding openings 122 formed in the offset portion 120 of the panel 110 and slidably engaging the tabs 212 with corresponding portions of the offset portion 120 of the panel 110 proximate the openings 122. In other embodiments, the indicator 200 may be mounted on at least one panel 110 by any other suitable device or method. Further, in other embodiments, any desired number of indicators 200 of the modular scoreboard 100 may be mounted on the panels 110, such as by the task 340 described above.

Further, in one embodiment, the method 300 includes a task 350 of connecting wiring 202 from a control module to the indicator 200. The wiring 202 (see FIG. 18), in one embodiment, is connected between the indicator 200 (e.g., an output device of the indicator 200) and a control module by passing the wiring 202 through the opening 214 in the rear side of the case 210 of the indicator 200 and the opening 124 formed in the offset portion 120 of the panel 110, and further by passing the wiring 202 through the conduit 140 between the substrate 10 and the offset portion 120 of the panel 110.

With further reference to FIG. 33, the method 300, in one embodiment, further includes a task 360 of mounting side rails to the panels. In one embodiment, with reference to FIG. 6, a first side rail 150 (e.g., a left side rail) is mounted to the first panel 110 (e.g., the left outermost panel) by inserting the tabs 134 of the coupling portion 132 of the first panel 110 into the openings 155 of the first side rail 150 and slidably engaging the first side rail 150 and, more specifically, corresponding portions of the flange 154 of the first side rail 150 proximate the openings 155 relative to the tabs 134. Further, in one embodiment, with further reference to FIG. 6, a second side rail 160 (e.g., a right side rail) is mounted to the second panel 110 (e.g., the right outermost panel) by inserting the tabs 164 of the second side rail 160 into the openings 135 of the second panel 110 and slidably engaging the tabs 164 of the second side rail 160 with corresponding portions of the flanges 114 proximate the openings 135 of the second panel 110. Alternatively, in other embodiments, side rails may be mounted to the outermost panels 110 of the modular scoreboard 100 by any other suitable device or method, such as via fasteners or welding.

In one embodiment, the method 300 further includes a task 370 of mounting a top cover and/or a bottom cover to the panels. A top cover and/or a bottom cover, such as one of the covers 172, 174, and 176 described above and shown in FIGS. 19-21, respectively, may be mounted to top edge portions and/or bottom edge portions of the panels 110, as described herein. More specifically, one of the covers 172, 174, and 176 may be pressed onto the edge portions of the panels 110 such that the respective slot 172a, 174a, and 176a receives the edge portions of the panels 110 and is coupled thereto by friction or fasteners. Alternatively, in other embodiments, a top cover and/or a bottom cover may be mounted to the panels 110 of the modular scoreboard 100 by any other suitable device or method. such as via fasteners or welding.

While in one embodiment, the method 300 of assembling a modular scoreboard may include each of the tasks described above and shown in FIG. 33, in other embodiments of the present invention, in a method of assembling a modular scoreboard, one or more of the tasks described above and shown in FIG. 33 may be absent and/or additional tasks may be performed. Further, in the method 300 of assembling a modular scoreboard according to one embodiment, the tasks may be performed in the order depicted in FIG. 33. However, in a method of assembling a modular scoreboard according to other embodiments of the present invention, the tasks described above and shown in FIG. 33 may be performed in any other suitable sequence.

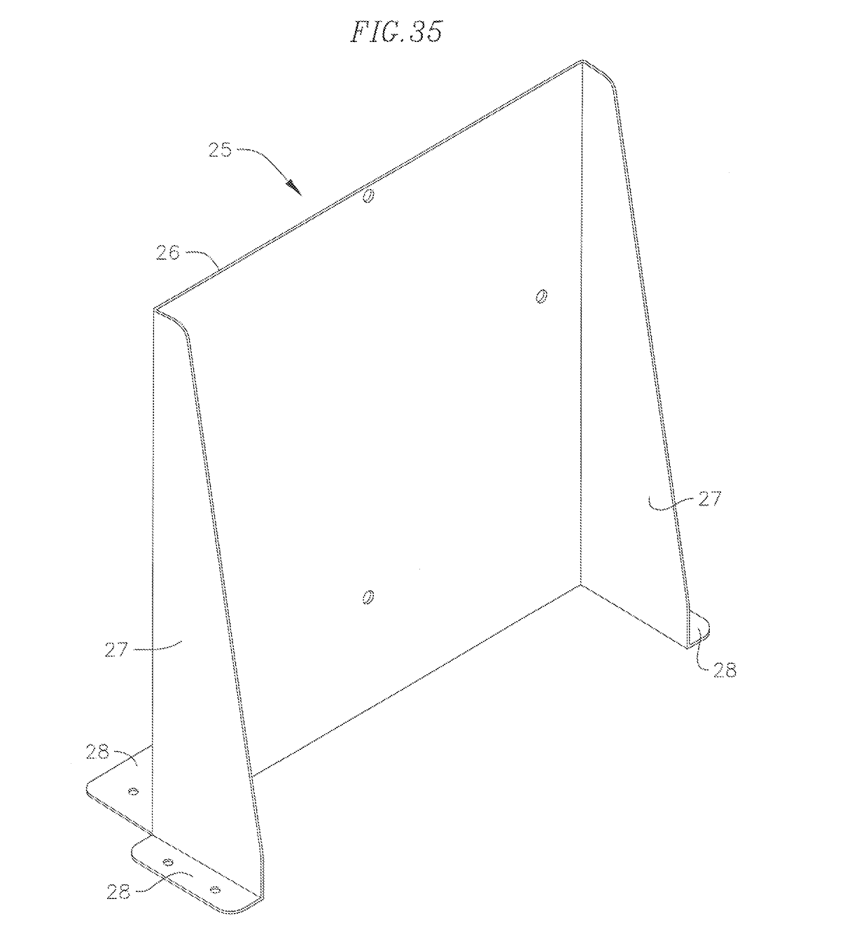

With reference to FIGS. 34 and 35, assembling a modular scoreboard according to an embodiment of the present invention may further include mounting a control module. As shown in FIG. 34, in one embodiment, a control module 20 is mounted to a structure 22 utilizing a mounting bracket 25. The structure 22, in one embodiment, is a side, top, or bottom surface of an existing scoreboard but alternatively, may be any other suitable structure including a portion of a modular scoreboard of the present invention. The mounting bracket 25 for mounting the control module 20, according to one embodiment, is shown in further detail in FIG. 35. The mounting bracket 25 may include a mounting portion 26 configured for mount the control module 20 thereto, one or more stiffener portions 27 extending from the mounting portion 26, and one or more flanges 28 extending from the mounting portion 26 and/or the stiffener portions 27. The mounting bracket 25 may be fastened to the structure 22 at the flanges 28. However, embodiments of the present invention are not limited thereto and, in other embodiments, a bracket for mounting a control module may have any other suitable configuration for mounting the control module to a top, side, or bottom surface of an existing scoreboard or other substrate or structure, or to the modular scoreboard itself.

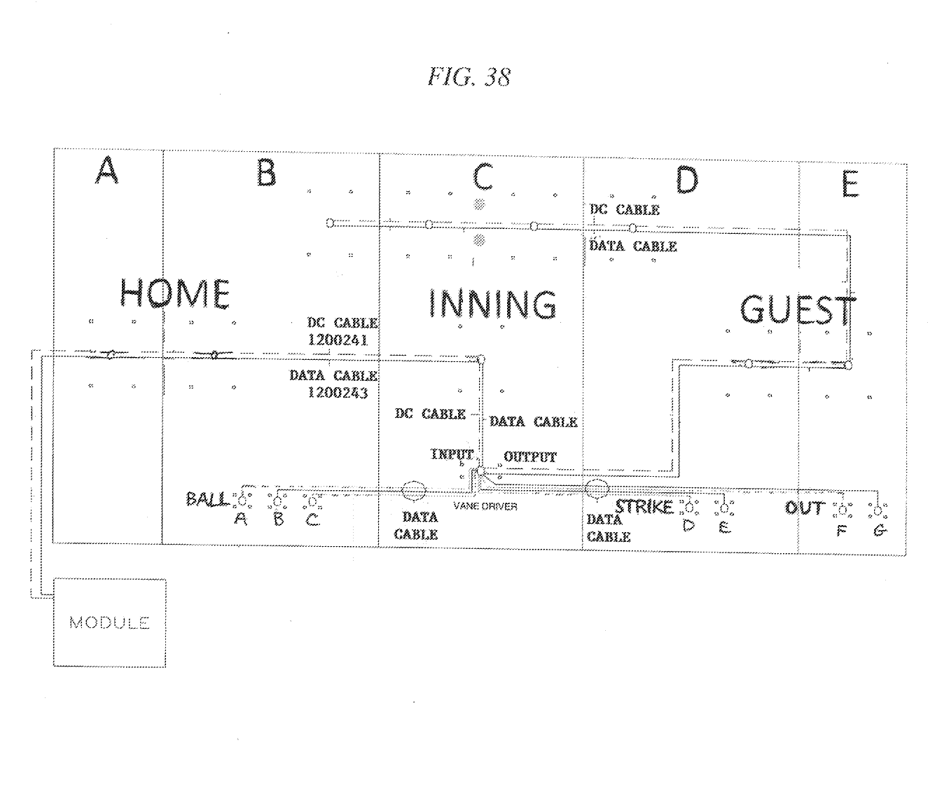

A method of assembling, or retrofitting, a modular scoreboard having five panels on an existing scoreboard according to one embodiment of the present invention is described below. Of course, as described above with respect to FIG. 33, some of the tasks described below may be omitted or performed in a different order, and also, additional tasks not described below may be performed as part of the method. With reference to FIG. 38, a schematic wiring layout is shown for the modular scoreboard assembled according to the method described below.
1. Unpack all items from both boxes and inspect for damage, and contents.
2. Disconnect and isolate all existing power from the old scoreboard. Electrician may be required.
3. Install module to mounting brackets using drill point screws.
4. Mount control module to the module mount using longer drill point screws. Wear safety glasses.

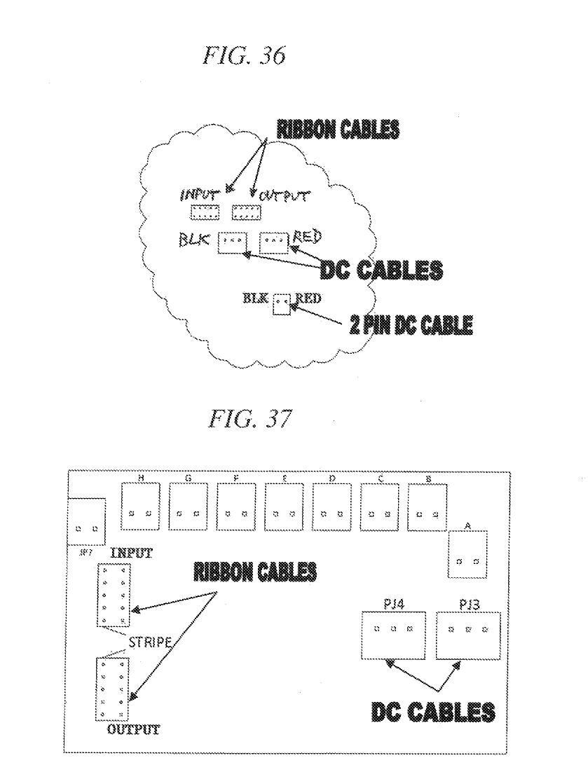

5. Mount control module and bracket assembly on the lower left of the scoreboard face by screwing bracket into the face. Logo should face out to the field.
6. Determine what type of existing scoreboard you have. There are two types this overlay will work with. First is a flush type where the sides and top are even with the edge of the face and back. The second is a recessed type where the sides and top are pushed in 1-2″ from the edge of the face and back.
7. Get panel A.
8. For the flush type, no modification is needed. For the recessed type, bend the tab (e.g., the tab 197 shown in FIG. 28) in 90 degrees.
9. Place panel A even with the edge of the existing scoreboard. Place it so that the tabs are either flush to the side, or wrapped around the edge of the face. It should be even with the top and bottom of the existing scoreboard.
10. Attach panel A to existing scoreboard using the longer drill point screws.
11. Attach conduit to hole in lower left of the face of panel A. The nut will have to be removed, wires passed through the hole, and then put back on to hold the fitting tight.
12. Run the wires to the oval hole between the two small rectangular holes in the panel. To do this, pull the panel out slightly away from the face of the old scoreboard.
13. Using the masking tape and marker, label both of these wires with the word “Input” or the letter “I”.
14. From the wiring kit, get one each of the following number wire. 1200243 and 1200241.
15. Label 1 end of each with “INPUT” or “I” and the other end of each with “OUTPUT” or
16. Run the output end of each wire through the same hole in the panel. Bend the wires over the panel gently so that they cannot fall back through the hole.
17. Using the masking tape, tape the wires horizontally away from the hole toward the right of the panel. Make sure not to run the wires under one of the tabs sticking out of the right side of panel A.
18. Using the ¾″ or shorter drill point screws, fasten the right edge of panel A to the face of the old scoreboard. If any protrusion from the face of the old scoreboard interferes with the flatness of panel A, the screw tab can be bent out of the way or cut off. Screws need to be installed in as many of the provided holes as possible.
19. Get panel B.
20. Install panel B into the right side of panel A. Align all the tabs sticking out of the left side of panel B with the slots in panel A. Once aligned, pull down on panel B until it is fully seated in the slot. Panel A and B should be even with each other on the top and the bottom.
21. Run the input end of the two wires from task 14 in the middle oval hole in panel B. This hole is level with the hole in panel A.
22. From the wiring kit, get one each of the following number wire: 1200491 and 1200244.
23. As before, label one end of each wire with “INPUT” or “I” and the other end of each with “OUTPUT” or “O”.
24. Run the input end of each of these wires through the middle hole just as was done with the other wires. You should now have 4 wire ends labeled hanging out of each of the middle oval holes.
25. From the wiring kit, get one each of the following wire numbers: 1200491 and 1200243.
26. Label the ends as before, put the output end of each wire through the oval hole at the top of panel B.
27. Using masking tape, tape the wires straight out horizontally onto the old scoreboard face.
28. From the wiring kit, get three of wire number 1200252.
29. Label one each of the wires with the letters A, B, &C.
30. Run one end of wire A through the leftmost lower oval hole. B goes in the second one and C in the last.
31. Fasten panel B to the old scoreboard face using the ¾″ long drill point screws.
32. Get three digit assemblies from the kit.
33. Reference FIG. 36 for wiring connection points on the back of the digit panel.
34. Take one digit assembly and go to lower hole in panel A. Connect the non labeled ribbon cable (flat grey cable) to the input terminal on the digit. Make sure to align the red strip on the cable with the point indicated on the back of the digit.
35. Connect the non labeled DC cable (three wire cable) to the RED DC cable connector on the back of the digit.
36. The remaining cables go an the output and BLK DC connectors on the digit.
37. Once all wires are connected, push any excess wire back into the panel face as you place the digit onto the face. The digit attaches in the same manner as the panels. Put the four tabs in the slot and push down until it is seated at the bottom of the slots.
38. Repeat for the two digits in panel B. The top digit only has the input wires to be connected. The connections on the lower digit are just like the first.
39. Get three dot assemblies from the kit.
40. The dot assemblies are easier to install being that there is only one cable to hook up to it.
41. Make sure to put the red wire and black wire on the correct labeled pin on the back of the dot board. Put the dot in the slots and push down to seat just as was done with the previous digits.
42. Get panel C.
43. Just as with panel B, align and seat panel C into panel B. Top and bottom should be even with panel B.
44. Begin working on the top digit location on panel C. Run the output end of the wires out the left most upper oval hole.
45. From the wiring kit, get 1 each of wire numbers 1000491 and 1200243. Label ends as before on INPUT and OUTPUT on each wire.
46. Install the INPUT end of each wire through the leftmost hole.
47. Run the OUTPUT end of the wires to the right oval hole in the top.
48. From the wire kit, get 1 each of wire numbers 1200241 and 1200243. Label the ends INPUT and OUTPUT.
49. Take the INPUT end and run it through the right oval hole. Run the OUTPUT end out horizontally and tape to face of old scoreboard.
50. From the wiring kit, get the remaining four wires numbered 1200252. Label the ends of wire 1 as “D”, wire 2 as “E”, wire 3 as “F” and wire 4 as “G”.
51. Install the vane driver box from the kit on the holes just below the inning digit holes.
52. Run the ends of wires A,B,C,D,E,F, and G through the vane driver oval hole and into the case.
53. Run the loose ends of D,E,F and G horizontally and tape to the face of the old scoreboard.
54. Run the INPUT ends of the wires from the second digit on panel B into the oval hole for the Inning digit.
55. From the wiring kit, get one each of wire numbers 1200241 and 1200243. Label the ends INPUT and OUTPUT as before.
56. Take the OUTPUT end of each wire and run it through the oval hole for the inning digit.
57. Take the INPUT end of each wire and run it through the oval hole and into the vane driver case.
58. From the wiring kit, get one each of wire numbers 1200244 and 1000491. Label the ends INPUT and OUTPUT as before.
59. Run the OUTPUT end of each wire through the hole and into the vane driver case. There should be eleven wires running through this hole at this point.
60. Run the INPUT ends of each wire out horizontally and tape to the face of the old scoreboard.
61. Fasten panel C to the face of the old scoreboard using drill point screws.
62. Get three digit assemblies from the kit.
63. Starting with the top right most digit, install and wire each digit as was done previously. Refer to tasks 32-37 for more information.
64. From the wiring kit, get the vane driver board.
65. Refer to FIG. 37 during wiring of the vane driver.
66. Connect wires A through G to the corresponding locations on the board.
67. Connect the INPUT labeled ribbon cable to the input connector and the OUTPUT labeled cable to the output connector. Pay attention to the stripe location on this.
68. Connect the INPUT end of the DC cable to the PJ3 connector. The OUTPUT DC cable connects to the PJ4 connector.
69. Place the vane driver board inside the case.
70. Install the cover over the case.
71. Get panel D from the kit.
72. Attach panel D to panel C.
73. Starting at the top, run the OUTPUT wires from the top right digit in panel C to the oval hole in the top of panel D.
74. From the wiring kit, get one each of wire numbers 1000491 and 1200252. Label the ends as INPUT and OUTPUT.
75. Run the INPUT labeled wires through the oval hole at the top of panel D. There should be four wires in the oval hole now.
76. Run the OUTPUT wires out horizontally and tape to the face of the old scoreboard.
77. Run the INPUT labeled wires from the inning digit to the oval hole in panel D.
78. From the kit, get one each of wire number 1200241 and 1200243. Label the ends INPUT and OUTPUT on each wire.
79. Run the OUTPUT labeled wires through the lower oval_hole in panel D.
80. Run wire “D” through left most dot location (strike 1).
81. Run wire “E” through right most dot location (strike 2).
82. Make sure that F and G wires are run out horizontally and taped.
83. Fasten panel D to the face of the old scoreboard using drill point screws.
84. Install two digit assemblies and two dot assemblies just as before in the proper locations.
85. Get panel E from the kit.
86. Attach panel E to panel D.
87. Run the OUTPUT wires from the top right digit in panel D to the oval digit hole in panel E.
88. Run the INPUT wires from the right digit in panel D to the oval hole in panel E.
89. Run the “F” wire to the left dot location in panel E. (Out 1).
90. Run the “G” wire to the right dot location in panel E. (Out 2).
91. Fasten panel E to the scoreboard using the same method as with panel A. The drill point screws for the flanged type scoreboard must be shorter than ¾′.
92. Install final digit assembly and two dot assemblies on panel E.
93. From the kit, get the pieces for the top and bottom covers.
94. Install the top cover by sliding it over the top of each panel. This adds strength and protection to the scoreboard. Attach each end of the strip to the face of the board with a drill point screw.
95. Installation of the bottom cover is the same as the top.
96. Running and connecting the electric service is recommended to be done by a licensed electrician. Service to board is suggested to be at least 120V/20A circuit. Remove the cover from the primary module and install wiring to connector block inside enclosure.
97. Replace cover on module housing.

As described above, a modular scoreboard according to embodiments of the present invention may be configured to be assembled or installed on an existing substrate, such as a retrofit onto an existing scoreboard. However, the existing substrate may alternatively be a wall, a building, a board, or any other existing panel or facade where the modular scoreboard is desired to be mounted. Further, a modular scoreboard according to embodiments of the present invention may be configured to be mounted on a structure other than a substrate, such as suspended from an overhead structure or mounted on two poles, or even stood up and propped against a wall or assembled with wheels to be moveable. Further, embodiments of the present invention are not limited to installation on an existing substrate or structure, but rather, may include a mounting substrate as a part of the modular scoreboard. A modular scoreboard incorporating a mounting substrate, for example, may be pre-wired and quickly mounted on a wall, fence, building, poles, or other structure at an installation site.

Although the drawings illustrate the invention as applied to a scoreboard for sporting events, it will be apparent that the novel aspects of the scoreboard of the invention may also be applied to other applications. For example, aspects of embodiments of a scoreboard described herein may be applied to a signboard or display board other than a scoreboard. Further, it will be apparent to those skilled in the art that a scoreboard may incorporate or embody various combinations of the embodiments described above with respect to the shapes, sizes, and components of the scoreboards, as well as alternatives not described herein, without departing from the spirit and scope of the present invention.

The preceding description has been presented with reference to some exemplary embodiments of the invention. Persons skilled in the art and technology to which this invention pertains will appreciate that alterations and changes in the described structures and methods of assembly and operation can be practiced without meaningfully departing from the principles, spirit, and scope of this invention.

What is claimed is:

1. A modular scoreboard comprising a plurality of panels coupled to one another and attachable to a substrate, wherein at least one panel of the plurality of panels comprises:
an attachment portion configured to attach the at least one panel to the substrate;
an offset portion coupled to the attachment portion and configured to be spaced apart from the substrate to provide a conduit between the offset portion and the substrate when the at least one panel is attached to the substrate; and
a coupling portion coupled to the offset portion and coupling the at least one panel to another panel of the plurality of panels.

2. The modular scoreboard of claim 1, wherein the substrate is a display panel of another scoreboard.

3. The modular scoreboard of claim 1, wherein the coupling portion comprises a tab received in an opening formed in the another panel and engaging a portion of the another panel proximate the opening, the tab being slidable relative to the opening for engaging the portion of the another panel.

4. The modular scoreboard of claim 1, further comprising an indicator mounted on the offset portion of the at least one panel.

5. The modular scoreboard of claim 4, wherein the at least one panel has at least one first opening formed in the offset portion, and the indicator comprises at least one tab received in the at least one first opening and engaging a portion of the offset portion proximate the at least one first opening, the at least one tab being slidable relative to the at least one first opening for engaging the portion of the offset portion.

6. The modular scoreboard of claim 5, wherein the at least one panel has a second opening formed in the offset portion for passing wiring connected to an output device of the indicator therethrough to the conduit.

7. The modular scoreboard of claim 5, wherein the indicator comprises:
a case comprising the at least one tab;
a cover mounted to the case; and
an output device enclosed by the case and the cover.

8. The modular scoreboard of claim 1, further comprising a hinge coupling panels of the plurality of panels to each other.

9. The modular scoreboard of claim 1, further comprising a display surface including outer surfaces of the panels.

10. The modular scoreboard of claim 9, further comprising a graphic design on the display surface.

11. The modular scoreboard of claim 1, further comprising at least one appendage portion coupled to at least one of the panels at a peripheral portion thereof.

12. The modular scoreboard of claim 1, further comprising a side rail coupled to a side of one of the panels and enclosing the conduit on the side of the panel.

13. The modular scoreboard of claim 1, further comprising a cover coupled to ends of the panels and enclosing the conduits of the panels on the ends.

14. The modular scoreboard of claim 1, wherein the at least one panel further comprises at least one stiffener on an inner surface of the offset portion.

15. The modular scoreboard of claim 1, wherein each panel of the plurality of panels comprises an attachment portion configured to attach the panel to the substrate.

16. A modular scoreboard comprising:
at least one panel comprising a display surface having at least one first opening; and
an indicator mounted on the at least one panel and comprising at least one tab received in the at least one first opening and engaging a portion of the at least one panel proximate the at least one first opening.

17. The scoreboard of claim 16, wherein the indicator comprises:
a case comprising the at least one tab;
a cover mounted to the case; and
an output device enclosed by the case and the cover.

18. The scoreboard of claim 17, wherein the display surface of the at least one panel has a second opening, and the case of the indicator has an opening corresponding to the second opening of the at least one panel, the opening of the indicator and the second opening of the at least one panel being configured to pass wiring therethrough for electrically connecting the output device to a control module.

19. The scoreboard of claim 16, wherein the at least one panel comprises a plurality of panels coupled to one another and attachable to a substrate, and the display surface is spaced apart from the substrate to define a conduit therebetween when the panels are attached to the substrate.

20. A method of assembling a modular scoreboard including a plurality of panels, the method comprising:
attaching panels of the plurality of panels to a substrate such that display portions of the panels are spaced apart from the substrate to define at least one conduit between the display portions and the substrate;
coupling the panels to one another; and
mounting an indicator on at least one of the panels.

21. The method of claim 20, wherein the substrate is a display panel of another scoreboard.

22. The method of claim 20, wherein coupling the panels to one another comprises inserting a tab of one of the panels into an opening formed in another one of the panels and slidably engaging the tab with a portion of the another one of the panels proximate the opening.

23. The method of claim 20, wherein mounting the indicator on the at least one of the panels comprises inserting at least one tab of a case of the indicator into at least one corresponding first opening formed in the display portion of the at least one of the panels and slidably engaging the at least one tab with at least one corresponding portion of the at least one of the panels proximate the at least one first opening.

24. The method of claim 23, further comprising electrically connecting an output device of the indicator to a control module through wiring passing through an opening of the case and a second opening formed in the display portion of the at least one of the panels.
